(19) United States
(12) Patent Application Publication
(10) Pub. No.: US 2026/0196806 A1
(43) Pub. Date: Jul. 9, 2026

(54) SURFACE EMITTING LASER

(71) Applicant: SONY GROUP CORPORATION, TOKYO (JP)

(72) Inventors: HIDEKI WATANABE, TOKYO (JP); RINTARO KODA, TOKYO (JP); GYONGSOK SONG, TOKYO (JP); YASUTAKA HIGA, TOKYO (JP); TATSUYA MATOU, TOKYO (JP); SHUHEI YAMAGUCHI, TOKYO (JP)

(21) Appl. No.: 18/871,358

(22) PCT Filed: May 17, 2023
(86) PCT No.: PCT/JP2023/018360

§ 371 Date: Sep. 10, 2025

(30) Foreign Application Priority Data
Jun. 10, 2022 (JP) 2022-094260

(51) Int. Cl. H01S 5/183; H01S 5/042

(52) U.S. Cl. CPC H01S 5/18311; H01S 5/04256; H01S 5/18347; H01S 5/18369

(57) ABSTRACT

To provide a surface emitting laser capable of reducing both series resistance and optical loss. A surface emitting laser according to the present technology includes: a first structure including a first reflector; a second structure that includes a second reflector and is stacked on the first structure; and an active layer disposed between the first and second structures, and a current injection layer is provided in a range in which a light intensity is 1/10 times or more and ⅖ times or less a peak intensity at least inside the first reflector and/or the second reflector. According to the surface emitting laser according to the present technology, it is possible to provide a surface emitting laser capable of reducing both series resistance and optical loss.

### TECHNICAL FIELD

The technology according to the present disclosure (hereinafter also referred to as “the present technology”) relates to a surface emitting laser.

### BACKGROUND ART

Conventionally, vertical cavity surface emitting lasers (VCSEL) are known.

Some of the surface emitting lasers have an intra-cavity structure in which a current injection layer is provided in a resonator constituent portion sandwiched between two reflectors. This intra-cavity structure has a problem of optical loss (particularly, light absorption by the current injection layer).

Therefore, there has been proposed a surface emitting laser in which a current injection layer is disposed in a spacer layer at a position where an envelope of light intensity of the standing wave is minimized among at least three spacer layers provided in a resonator constituent portion, or in the vicinity of this spacer layer (for example, see Patent Document 1).

### CITATION LIST

### Patent Document

Patent Document 1: Japanese Patent Application Laid-Open No. 2012-129245

### SUMMARY OF THE INVENTION

### Problems to be Solved by the Invention

However, in this surface emitting laser (for example, see Patent Document 1), there is room for improvement in reducing both series resistance and optical loss.

Therefore, a main object of the present technology is to provide a surface emitting laser capable of reducing both series resistance and optical loss.

### Solutions to Problems

The present technology provides a surface emitting laser including:
a first structure including a first reflector;
a second structure that includes a second reflector and is stacked on the first structure; and
an active layer disposed between the first and second structures, in which
a current injection layer is provided in a range in which a light intensity is 1/10 times or more and ⅖ times or less a peak intensity at least inside the first reflector and/or the second reflector.

The current injection layer may be disposed in a range in which a light intensity is 1/e² times or more and 1/e times or less the peak intensity.

The first reflector and/or the second reflector may include first and second constituent layers in this order from the active layer side, and the current injection layer may be disposed between the first and second constituent layers. The current injection layer may be thicker than the first constituent layer and thinner than the second constituent layer.

The current injection layer may include a compound semiconductor layer containing In.

The first reflector may include the first and second constituent layers, a mesa including the first constituent layer, the active layer, and the second reflector may be formed on the current injection layer, and an electrode may be provided on a region of the current injection layer around the mesa.

Another current injection layer may be provided between the active layer and the second reflector.

The second structure may include a cladding layer disposed between the active layer and the second reflector, and said another current injection layer may be disposed between the cladding layer and the second reflector.

The second structure may include a cladding layer disposed between the active layer and the second reflector, and said another current injection layer is provided at least inside the cladding layer.

Another mesa including the second reflector may be formed on said another current injection layer, and another electrode may be provided on a region of said another current injection layer around said another mesa.

The second reflector may include the first and second constituent layers, and a mesa including the second constituent layer is formed on the current injection layer, and an electrode is provided on a region of the current injection layer around the mesa.

Another current injection layer may be provided between the first reflector and the active layer.

The first structure may include a cladding layer disposed between the first reflector and the active layer, and said another current injection layer may be disposed between the first reflector and the cladding layer.

The first structure may include a cladding layer disposed between the first reflector and the active layer, and said another current injection layer is provided at least inside the cladding layer.

Another mesa including the active layer, the first constituent layer, and the current injection layer may be formed on said another current injection layer, and another electrode may be provided on a region of said another current injection layer around said another mesa.

The current injection layer may be provided at least inside the first and second reflectors. The first reflector may include first and second constituent layers in this order from the active layer side, the second reflector may include first and second constituent layers in this order from the active layer side, a first current injection layer as the current injection layer may be provided between the first and second constituent layers of the first reflector, and a second current injection layer as the current injection layer may be provided between the first and second constituent layers of the second reflector.

A first mesa including a first constituent layer of the first reflector, the active layer, the first constituent layer of the second reflector, and the second current injection layer may be formed on the first current injection layer, and a second mesa including the second constituent layer of the second reflector is formed on the second current injection layer, and
a first electrode may be provided on a region of the first current injection layer around the first mesa, and a second electrode may be provided on a region of the second current injection layer around the second mesa.

### BRIEF DESCRIPTION OF DRAWINGS

FIG. 1 is a cross-sectional view of a surface emitting laser according to a first embodiment of the present technology.

FIG. 2 is a plan view of a surface emitting laser according to the first embodiment of the present technology.

FIG. 3 is a diagram for describing a preferred arrangement of a current injection layer.

FIG. 4 is a graph illustrating a relationship between the number of pairs of the intermediate DBR and relative light intensity in a current injection layer.

FIG. 5 is a graph illustrating a relationship between the number of pairs of the intermediate DBR, an oscillation threshold gain, and slope efficiency.

FIG. 6 is a flowchart for describing an example of a method for manufacturing the surface emitting laser of FIG. 1.

FIG. 7 is a cross-sectional view for each process of an example of the method for manufacturing the surface emitting laser of FIG. 1.

FIG. 8 is a cross-sectional view for each process of an example of the method for manufacturing the surface emitting laser of FIG. 1.

FIG. 9 is a cross-sectional view for each process of an example of the method for manufacturing the surface emitting laser of FIG. 1.

FIG. 10 is a cross-sectional view for each process of the example of the method for manufacturing the surface emitting laser of FIG. 1.

FIG. 11 is a cross-sectional view of a surface emitting laser according to a second embodiment of the present technology.

FIG. 12 is a cross-sectional view of a surface emitting laser according to a third embodiment of the present technology.

FIG. 13 is a plan view of a surface emitting laser according to the third embodiment of the present technology.

FIG. 14 is a flowchart for describing an example of a method for manufacturing the surface emitting laser of FIG. 12.

FIG. 15 is a cross-sectional view for each process of the example of the method for manufacturing the surface emitting laser of FIG. 12.

FIG. 16 is a cross-sectional view for each process of the example of the method for manufacturing the surface emitting laser of FIG. 12.

FIG. 17 is a cross-sectional view for each process of the example of the method for manufacturing the surface emitting laser of FIG. 12.

FIG. 18 is a cross-sectional view for each process of the example of the method for manufacturing the surface emitting laser of FIG. 12.

FIG. 19 is a cross-sectional view for each process of the example of the method for manufacturing the surface emitting laser of FIG. 12.

FIG. 20 is a cross-sectional view of a surface emitting laser according to a fourth embodiment of the present technology.

FIG. 21 is a cross-sectional view of a surface emitting laser according to a fifth embodiment of the present technology.

FIG. 22 is a cross-sectional view of a surface emitting laser according to Modification 1 of the first embodiment of the present technology.

FIG. 23 is a cross-sectional view of a surface emitting laser according to Modification 2 of the first embodiment of the present technology.

FIG. 24 is a cross-sectional view of a surface emitting laser according to Modification 3 of the first embodiment of the present technology.

FIG. 25 is a cross-sectional view of a surface emitting laser according to Modification 4 of the first embodiment of the present technology.

FIG. 26 is a cross-sectional view of a surface emitting laser according to Modification 5 of the first of the present technology.

FIG. 27 is a cross-sectional view of a surface emitting laser according to Modification 6 of the first embodiment of the present technology.

FIG. 28 is a cross-sectional view of a surface emitting laser according to Modification 7 of the first embodiment of the present technology.

FIG. 29 is a cross-sectional view of a surface emitting laser according to Modification 8 of the first embodiment of the present technology.

FIG. 30 is a cross-sectional view of a surface emitting laser according to Modification 9 of the first embodiment of the present technology.

FIG. 31 is a cross-sectional view of a surface emitting laser according to Modification 1 of the second embodiment of the present technology.

FIG. 32 is a cross-sectional view of a surface emitting laser according to Modification 2 of the second embodiment of the present technology.

FIG. 33 is a cross-sectional view of a surface emitting laser according to a modification of the third embodiment of the present technology.

FIG. 34 is a cross-sectional view of a surface emitting laser according to a modification of the fourth embodiment of the present technology.

FIG. 35 is a cross-sectional view of a surface emitting laser according to a modification of the fifth embodiment of the present technology.

FIG. 36 is a diagram illustrating an application example of the surface emitting laser according to the first embodiment of the present technology to a distance measuring device.

FIG. 37 is a block diagram illustrating an example of a schematic configuration of a vehicle control system.

FIG. 38 is an explanatory diagram illustrating an example of installation positions of distance measuring devices.

### MODE FOR CARRYING OUT THE INVENTION

Hereinafter, preferred embodiments of the present technology will be described in detail with reference to the accompanying drawings. Note that, in the present specification and the drawings, components having substantially the same functional configurations are denoted by the same reference signs, and redundant descriptions are omitted. The embodiments described below illustrate representative embodiments of the present technology, and the scope of the present technology is not narrowly interpreted by these embodiments. In the present specification, even in a case where it is described that a surface emitting laser according to the present technology exhibits multiple effects, it suffices that the surface emitting laser according to the present technology exhibits at least one effect. The effects described in the present specification are merely examples and are not limited, and other effects may be exerted.

Furthermore, the description will be given in the following order.
0. Introduction
1. Surface emitting laser according to first embodiment of present technology
2. Surface emitting laser according to second embodiment of present technology
3. Surface emitting laser according to third embodiment of present technology
4. Surface emitting laser according to fourth embodiment of present technology
5. Surface emitting laser according to fifth embodiment of present technology
6. Modification of present technology
7. Application examples to electronic device
8. Example in which surface emitting laser is applied to distance measuring device
9. Example in which distance measuring device is mounted on mobile body

### 0. Introduction

In a vertical cavity surface emitting laser (Vertical cavity surface emitting laser: VCSEL), an intra-cavity structure in which a current injection layer is disposed in a resonator constituent portion between two reflectors is widely known. In a VCSEL having an intra-cavity structure, it is possible to reduce series resistance and efficiently inject a current into the active layer by injecting a current into the active layer via a current injection layer disposed near the active layer.

However, in the VCSEL having the intra-cavity structure, since the current injection layer is provided in the resonator constituent portion, even if the current injection layer is disposed at the node of the standing wave, there is a problem of optical loss (specifically, light absorption by the current injection layer).

Therefore, the inventors have developed a surface emitting laser according to the present technology as a surface emitting laser capable of reducing both series resistance and optical loss by devising the arrangement of the current injection layer.

Hereinafter, some embodiments of a surface emitting laser according to the present technology will be described.

### 1. Surface Emitting Laser According to First Embodiment of Present Technology

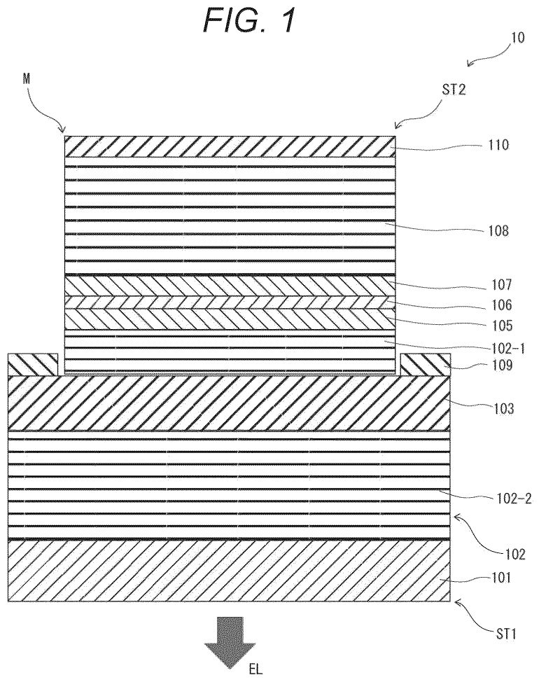

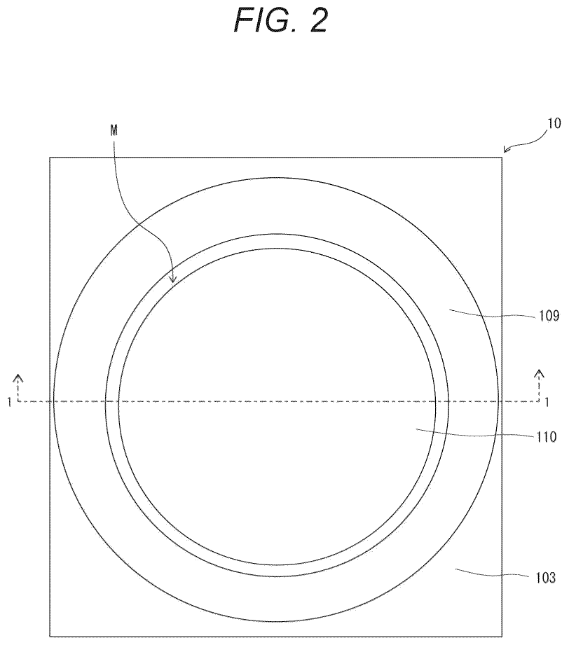

FIG. 1 is a cross-sectional view of a surface emitting laser 10 according to the first embodiment of the present technology. FIG. 2 is a plan view of the surface emitting laser 10. FIG. 1 is a cross-sectional view taken along line 1-1 in FIG. 2. Hereinafter, for the sake of convenience, the upper part in the cross-sectional view of FIG. 1 and the like will be described as an upper side, and the lower part in the cross-sectional view of FIG. 1 and the like will be described as a lower side.

### <<Configuration of Surface Emitting Laser>>

The surface emitting laser 10 according to the first embodiment of the present technology is a vertical cavity surface emitting laser (VCSEL). The surface emitting laser 10 is, for example, a backside emission type VCSEL.

As an example, as illustrated in FIGS. 1 and 2, the surface emitting laser 10 includes a first structure ST1 including a first reflector 102, a second structure ST2 that includes a second reflector 108 and is stacked on the first structure ST1, and an active layer 106 disposed between the first and second structures ST1 and ST2. That is, the surface emitting laser 10 has a vertical resonator structure in which the active layer 106 is sandwiched between the first and second reflectors 102 and 108 stacked on each other. As an example, the surface emitting laser 10 emits laser light (emitted light EL) from the back surface (lower surface) side of the substrate 101. The surface emitting laser 10 is driven by, for example, a laser driver. Hereinafter, a direction in which the first and second structures ST1 and ST2 are stacked (vertical direction) is also referred to as a “layering direction”.

The first structure ST1 further includes, as an example, a current injection layer 103, which is disposed at least inside the first reflector 102, a substrate 101, which is disposed on the opposite side of the first reflector 102 from the side corresponding to the active layer 106, and a first cladding layer 105, which is disposed between the first reflector 102 and the active layer 106.

The first reflector 102 includes first and second constituent layers 102-1 and 102-2 in this order from the side corresponding to the active layer 106. The current injection layer 103 is disposed between the first and second constituent layers 102-1 and 102-2.

A mesa M including the first constituent layer 102-1 of the first reflector 102, the active layer 106, and the second reflector 108 is formed on the current injection layer 103. That is, a region around the mesa M of the current injection layer 103 is exposed to the outside. A first electrode 109 (for example, n-side electrode: cathode electrode) is provided on a region around the mesa M of the current injection layer 103. The height of the mesa M is, for example, about 6 μm. Here, the planar view shape of the mesa M is circular, but may be other shapes such as an elliptical shape and a polygonal shape, for example.

The second structure ST2 further includes a second cladding layer 107 disposed between the second reflector 108 and the active layer 106. On the second reflector 108, a second electrode 110 (for example, p-side electrode: anode electrode) is provided.

Hereinafter, a section of the surface emitting laser 10 including the first and second cladding layers 105 and 107 and the active layer 106 and sandwiched between the first and second reflectors 102 and 108 is also referred to as a “resonator constituent portion”. A resonator is configured by including the first and second reflectors 102 and 108 and a resonator constituent portion.

### (Substrate)

As an example, the substrate 101 includes a semi-insulating GaAs substrate (i-GaAs substrate). Note that the substrate 101 may be a semiconductor substrate (for example, a GaAs substrate) of a first conductivity type (for example, n-type).

### (First Reflector)

The first reflector 102 is, for example, a semiconductor multilayer film reflector. The multilayer film reflector is also referred to as a distributed Bragg reflector (DBR).

The first constituent layer 102-1 of the first reflector 102 is a semiconductor multilayer film reflector (semiconductor multilayer film reflector including an impurity semiconductor) of the first conductivity type (for example, n-type). The second constituent layer 102-2 of the first reflector 102 is an undoped (i-type) semiconductor multilayer film reflector (semiconductor multilayer film reflector including an intrinsic semiconductor). As an example, each of the first and second constituent layers 102-1 and 102-2 includes a compound semiconductor (GaAs-based compound semiconductor) lattice-matched with GaAs. More specifically, each of the first and second constituent layers 102-1 and 102-2 has, as an example, a laminated structure in which a high refractive index layer (for example, n-GaAs) and a low refractive index layer (for example, n-AlGaAs) are alternately stacked. The optical thickness of each refractive index layer is ¼ of the oscillation wavelength λ.

The number of pairs of the first constituent layer 102-1 is, for example, two pairs. The number of pairs of the second constituent layer 102-2 is, for example, 16 pairs.

### (First Cladding Layer)

As an example, the first cladding layer 105 includes a GaAs-based compound semiconductor (for example, n-AlGaAs) of the first conductivity type (for example, n-type). The “cladding layer” is also referred to as a “spacer layer”.

### (Active Layer)

As an example, the active layer 106 has a quantum well structure including a barrier layer including a GaAs-based compound semiconductor (for example, InGaAs) and a quantum well layer designed to have an emission wavelength λ of 910 to 950 nm. This quantum well structure may be a single quantum well structure (QW structure) or a multiple quantum well structure (MQW structure). Note that the active layer 106 may have multiple QW structures or multiple MQW structures stacked via tunnel junctions.

### (Second Cladding Layer)

The second cladding layer 107 is formed by a GaAs-based compound semiconductor (for example, p-AlGaAs) of a second conductivity type (for example, p-type). The “cladding layer” is also referred to as a “spacer layer”.

### (Second Reflector)

The second reflector 108 is, for example, a semiconductor multilayer film reflector. The second reflector 108 is a semiconductor multilayer film reflector (semiconductor multilayer film reflector including an impurity semiconductor) of the second conductivity type (for example, p-type). As an example, the second reflector 108 includes a compound semiconductor (GaAs-based compound semiconductor) lattice-matched with GaAs. The second reflector 108 has a laminated structure in which a high refractive index layer (for example, p-GaAs) and a low refractive index layer (for example, p-AlGaAs) are alternately stacked. The optical thickness of each refractive index layer is ¼ of the oscillation wavelength λ. The number of pairs of the second reflector 108 is, for example, 35 pairs. The reflectance of the second reflector 108 is set slightly lower than that of the first reflector 102.

Hereinafter, the second constituent layer 102-2, which is a lower DBR closest to the substrate 101, is also referred to as a “lower DBR”, the second reflector 108, which is an upper DBR farthest from the substrate 101, is also referred to as an “upper reflector”, and the first constituent layer 102-1, which is a DBR disposed between the second constituent layer 102-2 and the second reflector 108, is also referred to as an “intermediate DBR”.

### (First Electrode)

The first electrode 109 is provided in a frame shape (for example, a ring shape) on the current injection layer 103 so as to surround the mesa M. As an example, the first electrode 109 has a laminated structure of AuGe/Ni/Au. In the laminated structure, AuGe, Ni, and Au have film thicknesses of 150 nm, 50 nm, and 200 nm, respectively, as an example. Note that the first electrode 109 may have a single-layer structure. The first electrode 109 is connected to, for example, the cathode side of the laser driver.

### (Second Electrode)

As an example, the second electrode 110 is solidly provided on the second reflector 108. As an example, the second electrode 110 has a laminated structure of Ti/Pt/Au. In the laminated structure, Ti, Pt, and Au have film thicknesses of 50 nm, 100 nm, and 200 nm, respectively, as an example. Note that the second electrode 110 may have a single-layer structure. The second electrode 110 is connected to, for example, the anode side of the laser driver.

### (Current Injection Layer)

Here, the current injection layer 103 plays a role of injecting a current flowing into the mesa M via the second electrode 110 as an anode electrode and passing through the second reflector 108, the second cladding layer 107, the active layer 106, the first cladding layer 105, and the first constituent layer 102-1 of the first reflector 102 into the first electrode 109 as a cathode electrode. The current injection layer 103 contributes to the improvement of current injection efficiency into the active layer 106.

As an example, the current injection layer 103 includes a highly doped layer (low resistance layer having high carrier conductivity), which is a compound semiconductor layer highly doped with impurities. The current injection layer 103 is also referred to as a “contact layer”. Here, as an example, the current injection layer 103 includes a GaAs layer (n-GaAs layer) doped with an n-type impurity. Examples of the n-type impurity (dopant) doped in the current injection layer 103 include Si, Se, Te, and Ge. The impurity concentration in the current injection layer 103 is preferably 1×10¹⁷ cm⁻³ or more and 1×10¹⁹ cm⁻³ or less, for example. Here, the current injection layer 103 is doped with Si as an impurity at a high concentration (for example, 3×10¹⁸ cm⁻³).

The optical thickness of the current injection layer 103 is preferably 50 nm or more and 2000 nm or less, for example. Here, the optical thickness of the current injection layer 103 is, for example, the same as A (oscillation wavelength).

As an example, the current injection layer 103 is preferably provided in a first range in which the light intensity in the resonator is 1/10 times (0.1 times) or more and ⅖ times (0.4 times) or less the peak intensity at least inside the first reflector 102. The first range is a range in which both series resistance and optical loss (particularly, light absorption by the current injection layer 103) can be reduced. Note that the reduction of the series resistance leads to the reduction of the driving voltage. The current injection layer 103 may be disposed, for example, at a position between one end of the first range (a position where the light intensity is 0.1 times the peak intensity) and the center of the first range (a position where the light intensity is 0.25 times the peak intensity). The current injection layer 103 may be disposed, for example, at a position between the other end of the first range (position where the light intensity is 0.4 times) and the center of the first range (position where the light intensity is 0.25 times the peak intensity of the light intensity).

The current injection layer 103 is more preferably disposed in a second range in which the light intensity in the resonator is 1/e² times or more and 1/e times or less the peak intensity.

The current injection layer 103 may be disposed, for example, at a position between one end of the second range (a position where the light intensity is 1/e² times the peak intensity) and the center of the second range (a position where the light intensity is (1/e² +1/e)×0.5 times the peak intensity). The current injection layer 103 may be disposed, for example, at a position between the other end of the second range (position where the light intensity is 1/e times the peak intensity) and the center of the second range (position where the light intensity is (1/e²+1/e)×0.5 times the peak intensity).

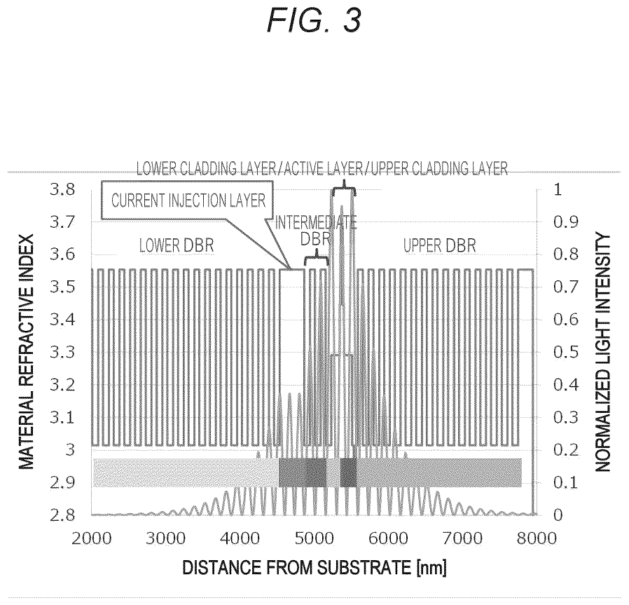

FIG. 3 is a diagram for explaining a suitable position of the current injection layer. Specifically, FIG. 3 is a graph illustrating an example in which the current injection layer 103 is disposed in a range in which the light intensity in the resonator is 1/e times (about 0.37 times) the peak intensity. In FIG. 3, the horizontal axis represents the distance [nm] from the substrate 101, the left vertical axis represents the material refractive index of each DBR, and the right vertical axis represents the normalized light intensity (relative light intensity when the peak intensity is 1). The light intensity distribution in the resonator is a Gaussian distribution centered on the center in the layering direction of the active layer.

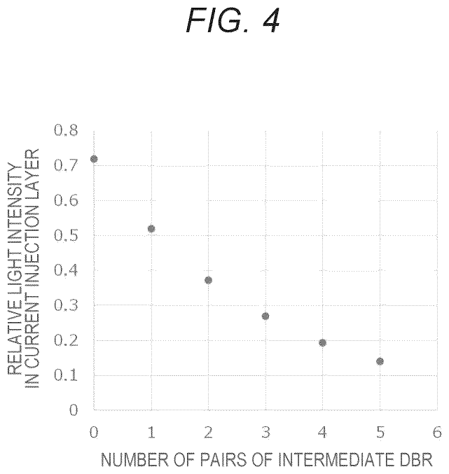

The position of the current injection layer 103 in the layering direction depends on the number of pairs (thickness) of the intermediate DBR. Conversely, the number of pairs (thickness) of the intermediate DBR depends on the position of the current injection layer 103 in the layering direction. FIG. 4 is a graph illustrating a relationship between the number of pairs of the intermediate DBR and the relative light intensity (normalized by peak intensity 1) in the current injection layer. In each of the first and second ranges described above, as the position of the current injection layer 103 is farther from the active layer 106 (as the number of pairs of the intermediate DBR is larger), the relative light intensity in the current injection layer 103 decreases and the optical loss decreases, but the series resistance increases. That is, in each of the first and second ranges, the position closest to the active layer 106 is the position where the series resistance can be minimized, and the position farthest from the active layer 106 is the position where the optical loss can be minimized. As described above, regarding the arrangement of the current injection layer 103, the series resistance and the optical loss are in a trade-off relationship.

In the example of FIG. 3, the current injection layer 103 is disposed at a position closest to the active layer 106 in the second range. This position is a position where the series resistance can be most reduced in the second range. The current injection layer 103 is closer to the active layer 106 when the number of pairs of the intermediate DBR is smaller, and is farther from the active layer 106 when the number of pairs of the intermediate DBR is larger. In the example of FIG. 3, the number of intermediate DBR pairs is two, the number of pairs of the lower DBR is 34, and the number of pairs of the upper DBR is 16.

On the other hand, it is assumed that the current injection layer 103 is disposed at a position farthest from the active layer 106 in the second range where the light intensity is 1/e² times (about 0.135 times) the peak intensity (at a position where the number of pairs of the intermediate DBR is five, for example, see FIG. 4). This position is a position where the optical loss can be most reduced in the second range.

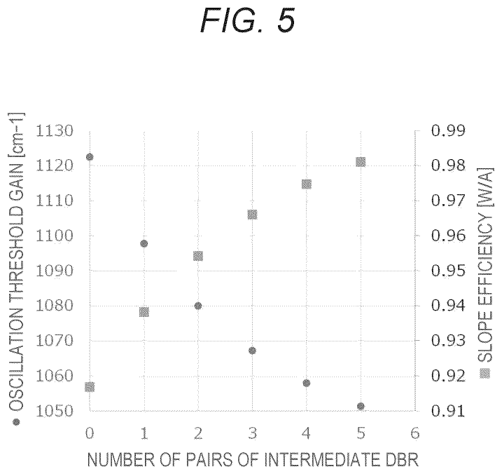

FIG. 5 is a graph illustrating a relationship between the number of pairs of the intermediate DBR, oscillation threshold gain, and slope efficiency. The oscillation threshold gain (● in FIG. 5) decreases as the number of pairs of the intermediate DBR increases (as the reflectance of the intermediate DBR increases). The slope efficiency (▪in FIG. 5) increases as the number of pairs of the intermediate DBR increases (as the series resistance increases). In this manner, the oscillation threshold gain and the slope efficiency are in a trade-off relationship with respect to the number of pairs of the intermediate DBR. From FIG. 5, by setting the number of pairs of the intermediate DBR to, for example, one to three pairs (preferably two pairs), both the oscillation threshold gain and the slope efficiency can be set to suitable values.

From the above, from the viewpoint of reducing both the series resistance and the optical loss, the number of pairs of the intermediate DBR is preferably, for example, one to six pairs (corresponding to the first range), and is preferably, for example, two to five pairs (corresponding to the second range). In addition, from the viewpoint of setting both the oscillation threshold gain and the slope efficiency to suitable values, the number of pairs of the intermediate DBR is preferably one to three pairs, for example, and more preferably two pairs, for example.

The current injection layer 103 is preferably thicker than the first constituent layer 102-1 (intermediate DBR) of the first reflector 102 and thinner than the second constituent layer 102-2 (lower DBR). Therefore, the electrical resistance in the in-plane direction (lateral direction) in the current injection layer 103 can be reduced, the electrical resistance in the layering direction (longitudinal direction) in the intermediate DBR can be reduced, and the reflectance can be gained in the lower DBR. Note that the current injection layer 103 may be thinner than the first constituent layer 102-1, and the first constituent layer 102-1 may be thinner than the second constituent layer 102-2.

The current injection layer 103 preferably includes a compound semiconductor layer containing In (for example, InGaP). The compound semiconductor layer containing In is preferably a surface layer on the side corresponding to the active layer 106 of the current injection layer 103. As a result, the compound semiconductor layer containing In can function as an etching stop layer at the time of forming the mesa M.

### <<Operation of Surface Emitting Laser>>

Hereinafter, the operation of the surface emitting laser 10 will be briefly described. In the surface emitting laser 10, for example, a current supplied from the anode side of the laser driver and flowing in from the second electrode 110 (anode electrode) is injected into the active layer 106 through the second reflector 108 and the second cladding layer 107 in this order. At this time, the active layer 106 emits light, and the light reciprocates between the first and second reflectors 102 and 108 while being amplified by the active layer 106, and is emitted from the back surface of the substrate 101 as the emitted light EL when the oscillation condition is satisfied. The current that has passed through the active layer 106 reaches the first electrode 109 (cathode electrode) through the first cladding layer 105, the first constituent layer 102-1 of the first reflector 102, and the current injection layer 103 in this order, and flows out from the first electrode 109 to, for example, the cathode side of the laser driver.

### <<Method for Manufacturing Surface Emitting Laser>>

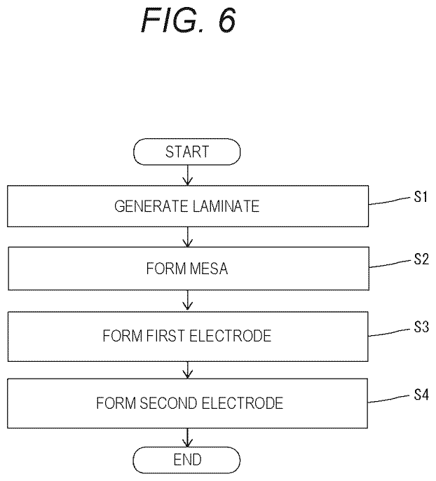

Hereinafter, a method for manufacturing the surface emitting laser 10 will be described with reference to the flowchart of FIG. 6 and the like. Here, as an example, multiple surface emitting lasers 10 are simultaneously generated on one wafer (hereinafter also referred to as a “substrate 101” for convenience) which is a base material of the substrate 101 by a semiconductor manufacturing method using a semiconductor manufacturing apparatus. Next, the multiple continuous and integrated surface emitting lasers 10 are separated from each other to obtain multiple chip-shaped surface emitting lasers 10.

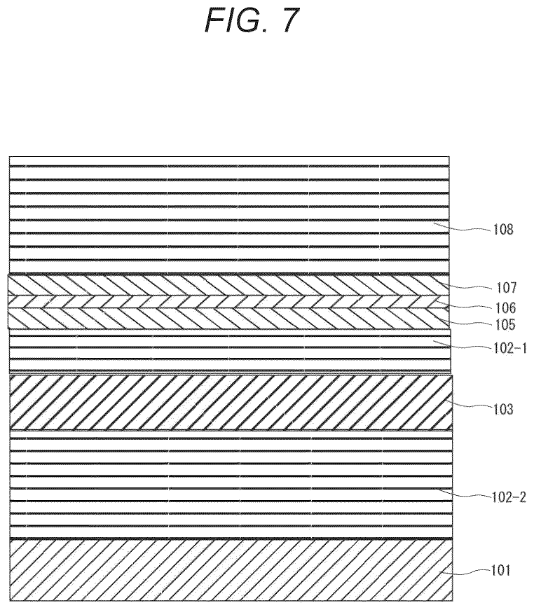

In the first step S1, a laminate is generated (see FIG. 7). Specifically, for example, the second constituent layer 102-2 of the first reflector 102, the current injection layer 103, the first constituent layer 102-1 of the first reflector 102, the first cladding layer 105, the active layer 106, the second cladding layer 107, and the second reflector 108 are stacked in this order (for example, epitaxially grown at a growth temperature of 605° C.) on a substrate 101 (for example, an i-GaAs substrate) as a growth substrate by a metal organic chemical vapor deposition (MOCVD) method to generate a laminate. Note that when MOCVD is performed, for example, trimethylgallium ((CH₃)₃Ga) is used as a source gas of gallium, for example, trimethylaluminum ((CH₃)₃Al) is used as a source gas of aluminum, for example, trimethylindium ((CH₃)₃In) is used as a source gas of indium, and for example, trimethylarsine ((CH₃)₃As) is used as a source gas of As. Furthermore, as a source gas of silicon, for example, monosilane (SiH₄) is used, and as a source gas of carbon, for example, carbon tetrabromide (CBr₄) is used.

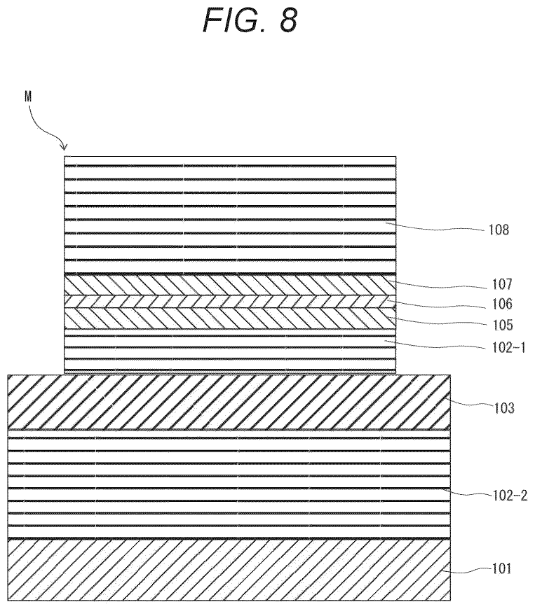

In the next step S2, a mesa M is formed (see FIG. 8). Specifically, first, a resist pattern that covers a portion where the mesa M is to be formed on the surface (upper surface) of the laminate on the side corresponding to the second reflector 108 is formed by photolithography. Next, using the resist pattern as a mask, the laminate is etched by inductively coupled plasma (ICP) dry etching using, for example, Cl₂, SiCl₄, or Ar until the current injection layer 103 is exposed, and the mesa M is formed on the current injection layer 103. At this time, if the surface layer of the current injection layer 103 on the side corresponding to the active layer 106 is the etching stop layer (for example, InGaP), etching of the current injection layer 103 can be more reliably suppressed. Thereafter, the resist pattern is removed.

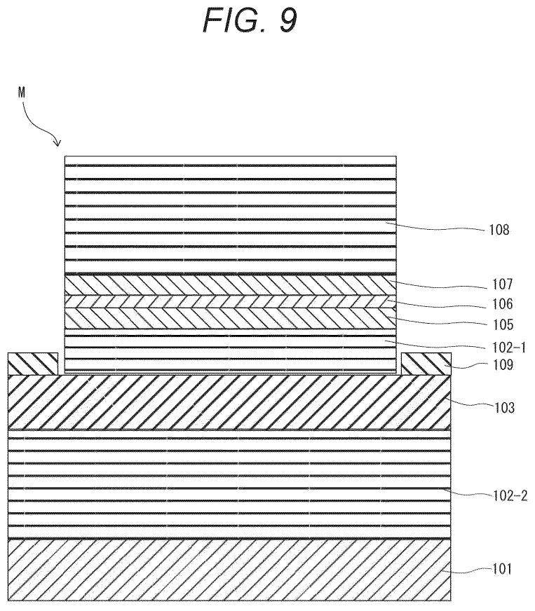

In the next step S3, the first electrode 109 is formed (see FIG. 9). Specifically, for example, using a lift-off method, the first electrode 109 is formed in a frame shape (for example, a ring shape) on a region around the mesa M of the current injection layer 103 so as to surround the mesa M. At this time, vacuum deposition, sputtering, or the like is used to form a film of the electrode material of the first electrode 109.

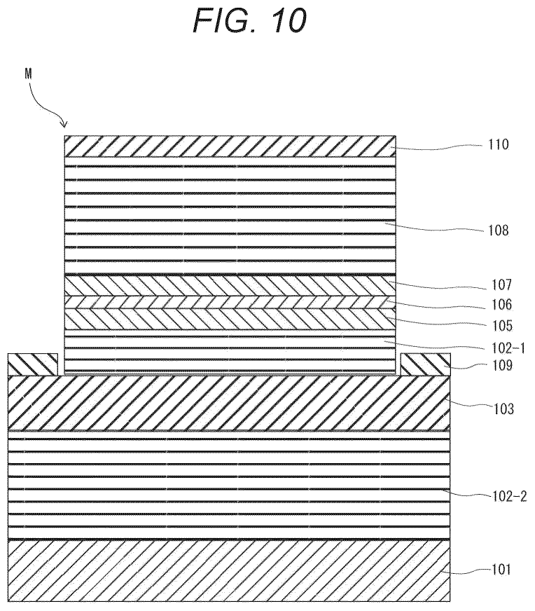

In the final step S4, the second electrode 110 is formed (see FIG. 10). Specifically, for example, the second electrode 110 is formed in a solid shape on the top portion of the mesa M (the upper surface of the second reflector 108) by using a lift-off method. At this time, vacuum deposition, sputtering, or the like is used to form a film of the electrode material of the second electrode 110.

### <<Effects of Surface Emitting Laser>>

Hereinafter, the effects of the surface emitting laser 10 will be described. A surface emitting laser 10 according to the first embodiment of the present technology includes a first structure ST1 including a first reflector 102, a second structure ST2 that includes a second reflector 108 and is stacked on the first structure ST1, and an active layer 106 disposed between the first and second structures ST1 and ST2, and a current injection layer 103 is provided at least inside the first reflector 102 in a range in which a light intensity is 1/10 times or more and ⅖ times or less the peak intensity.

In this case, the current injection layer 103 is disposed at a position where both series resistance and optical loss can be reduced.

As a result, according to the surface emitting laser 10, it is possible to provide a surface emitting laser capable of reducing both series resistance and optical loss.

The current injection layer 103 is more preferably disposed in the range in which the light intensity in the resonator is 1/e² times or more and 1/e times or less the peak intensity. Therefore, both series resistance and optical loss can be sufficiently reduced.

The first reflector 102 has first and second constituent layers 102-1 and 102-2 in this order from the side corresponding to the active layer 106, and the current injection layer 103 is disposed between the first and second constituent layers 102-1 and 102-2. Therefore, since the first constituent layer 102-1, which is a part of the first reflector 102, can be positioned between the current injection layer 103 and the active layer 106, the oscillation threshold gain can be increased by the first constituent layer 102-1, and light absorption in the current injection layer 103 can be reduced.

The first constituent layer 102-1 is a multilayer film reflector with the number of pairs being one pair or more and six pairs or less. Therefore, at least one of the series resistance, the light absorption by the current injection layer 103, the oscillation threshold gain, or the slope efficiency can be set to a suitable value.

The current injection layer 103 is preferably thicker than the first constituent layer 102-1 and thinner than the second constituent layer 102-2. This makes it possible to further reduce the series resistance while maintaining the reflectance of the first reflector 102.

The current injection layer 103 includes a compound semiconductor layer having an impurity concentration of 1×10¹⁷ cm⁻³ or more and 1×10¹⁹ cm⁻³ or less. Therefore, it is possible to balance reduction in resistance and reduction in light absorption of the current injection layer 103.

The current injection layer 103 preferably includes a compound semiconductor layer containing In. This makes it possible to limit etching of the current injection layer 103 at the time of forming the mesa M.

The first reflector 102 includes first and second constituent layers 102-1 and 102-2, a mesa M including the first constituent layer 102-1, the active layer 106, and the second reflector 108 is formed on the current injection layer 103, and the first electrode 109 is provided on a region of the current injection layer 103 around the mesa M. Therefore, the first electrode 109 can be provided on the current injection layer 103 by a simple method.

Each of the first and second constituent layers 102-1 and 102-2 is a semiconductor multilayer film reflector. Of the first and second constituent layers 102-1 and 102-2, the first constituent layer 102-1 closer to the active layer 106 includes an impurity semiconductor, and the second constituent layer 102-2 farther from the active layer 106 includes an intrinsic semiconductor. Therefore, conduction can be established between the active layer 106 and the current injection layer 103, diffusion of a current to the side corresponding to the second constituent layer 102-2 can be suppressed, and the current density in the current injection layer 103 can be increased.

As can be seen from the above description, according to the surface emitting laser 10, light absorption by the current injection layer 103 can be reduced without unnecessarily increasing the resonator length, and the driving voltage (series resistance) and the optical loss can thus be reduced.

### 2. Surface Emitting Laser According to Second Embodiment of Present Technology

### <<Configuration of Surface Emitting Laser>>

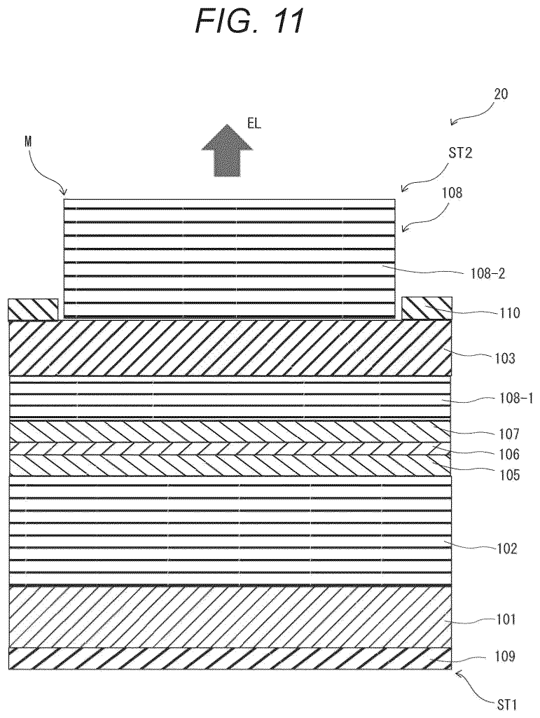

FIG. 11 is a cross-sectional view of a surface emitting laser 20 according to a second embodiment of the present technology. As illustrated in FIG. 11, the surface emitting laser 20 has a configuration substantially similar to that of the surface emitting laser 10 according to the first embodiment except that the second reflector 108 has the first and second constituent layers 108-1 and 108-2 in this order from the side corresponding to the active layer 106, and a current injection layer 103 is disposed between the first and second constituent layers 108-1 and 108-2.

In the surface emitting laser 20, a mesa M including the second constituent layer 108-2 of the second reflector 108 is formed on the current injection layer 103. The second electrode 110 is provided on a region of the current injection layer 103 around the mesa M. As an example, the second electrode 110 is provided in a frame shape (for example, a ring shape) so as to surround the mesa M. The first electrode 109 is solidly provided on the back surface (lower surface) of the substrate 101. The first reflector 102 is disposed between the substrate 101 and the first cladding layer 105.

In the surface emitting laser 20, the substrate 101 includes GaAs (for example, n-GaAs) of the first conductivity type (for example, n-type). The first reflector 102 (lower DBR) includes a GaAs-based semiconductor multilayer film reflector (for example, n-GaAs/n-AlGaAs) of a first conductivity type (for example, n-type). The number of pairs of the first reflector 102 is, for example, 34 pairs. The first constituent layer 108-1 (intermediate DBR) of the second reflector 108 includes a GaAs-based semiconductor multilayer film reflector (for example, p-GaAs/p-AlGaAs) of the second conductivity type (for example, p-type). The number of pairs of the first constituent layer 108-1 is, for example, two pairs. The current injection layer 103 includes p-type GaAs (p-GaAs), for example. As an example, the current injection layer 103 is doped with a p-type impurity (for example, C) at a high concentration (for example, 1×10¹⁹ cm⁻³). The optical thickness of the current injection layer 103 is, for example, λ. The second reflector 108 is an i-type GaAs-based semiconductor multilayer film reflector (for example, GaAs/AlGaAs). The number of pairs of the second reflector 108 is, for example, 16 pairs. Note that the second reflector 108 may be, for example, a GaAs-based semiconductor multilayer film reflector (for example, p-GaAs/p-AlGaAs) of the second conductivity type (for example, p-type).

In the surface emitting laser 20, the reflectance of the first reflector 102 is set to be slightly higher than the reflectance of the second reflector 108, and laser light is emitted from the upper surface of the second reflector 108.

That is, the surface emitting laser 20 is a surface emission type surface emitting laser.

### <<Operation of Surface Emitting Laser>>

Hereinafter, the operation of the surface emitting laser 20 will be described. In the surface emitting laser 20, for example, the current supplied from the anode side of the laser driver and flowing in from the second electrode 110 (anode electrode) is injected into the active layer 106 through the current injection layer 103, the first constituent layer 108-1 of the second reflector 108, and the second cladding layer 107 in this order. At this time, the active layer 106 emits light, and the light reciprocates between the first and second reflectors 102 and 108 while being amplified by the active layer 106, and is emitted from the upper surface of the second reflector 108 as the emitted light EL when the oscillation condition is satisfied. The current that has passed through the active layer 106 reaches the first electrode 109 (cathode electrode) through the first cladding layer 105, the first reflector 102, and the substrate 101 in this order, and flows out from the first electrode 109 to, for example, the cathode side of the laser driver.

### <<Method for Manufacturing Surface Emitting Laser>>

The surface emitting laser 20 can be manufactured by a manufacturing method according to the method for manufacturing the surface emitting laser 10 according to the first embodiment.

### <<Effects of Surface Emitting Laser>>

According to the surface emitting laser 20, it is possible to obtain effects substantially similar to those of the surface emitting laser 10 according to the first embodiment.

### 3. Surface Emitting Laser According to Third Embodiment of Present Technology

### <<Configuration of Surface Emitting Laser>>

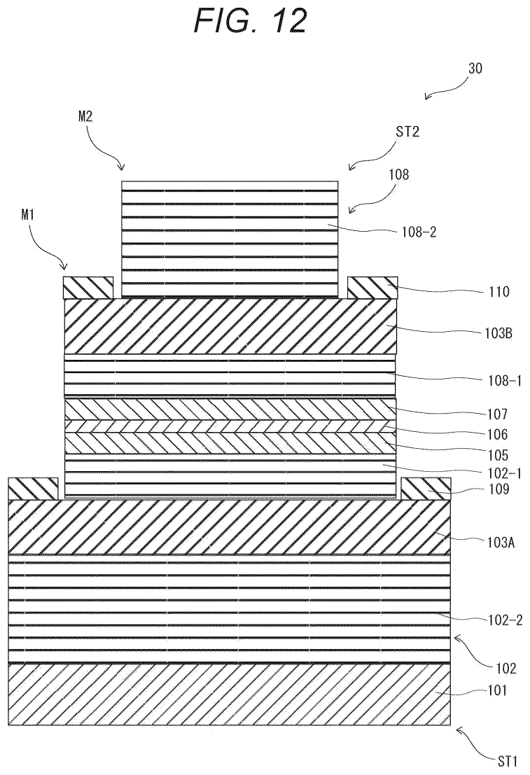

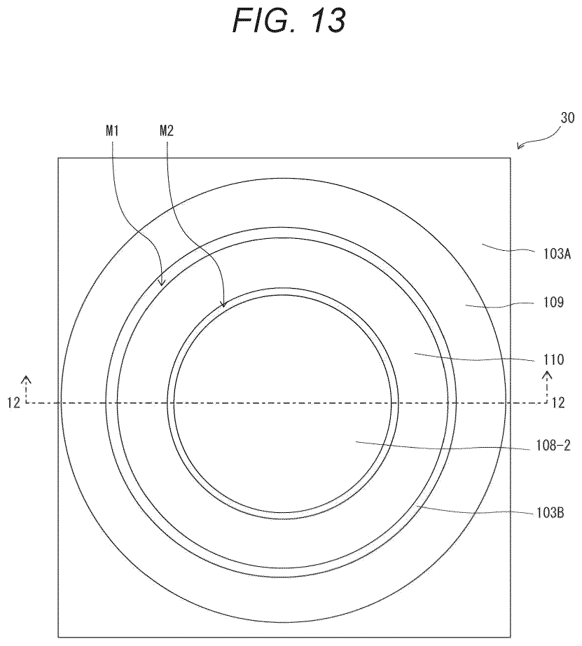

FIG. 12 is a cross-sectional view of a surface emitting laser 30 according to a third embodiment of the present technology. FIG. 13 is a plan view of the surface emitting laser 30. FIG. 12 is a cross-sectional view taken along line 12-12 in FIG. 13. The surface emitting laser 30 has a configuration substantially similar to that of the surface emitting laser 10 according to the first embodiment except that a first current injection layer 103A as a current injection layer 103 is provided at least inside the first reflector 102 and a second current injection layer 103B as a current injection layer 103 is provided at least inside the second reflector 108.

In the surface emitting laser 30, the first reflector 102 includes first and second constituent layers 102-1 and 102-2 in this order from the side corresponding to the active layer 106. The second reflector 108 includes first and second constituent layers 108-1 and 108-2 in this order from the side corresponding to the active layer 106. The first current injection layer 103A as the current injection layer 103 is provided between the first and second constituent layers 102-1 and 102-2 of the first reflector 102. The second current injection layer 103B as the current injection layer 103 is provided between the first and second constituent layers 108-1 and 108-2 of the second reflector 108.

In the surface emitting laser 30, a semi-insulating GaAs substrate (i-GaAs substrate) is used as the substrate 101. The second constituent layer 102-2 of the first reflector 102 is an undoped (i-type) GaAs-based semiconductor multilayer film reflector (for example, i-GaAs/i-AlGaAs). The number of pairs of the second constituent layer 102-2 is, for example, 34 pairs. The first current injection layer 103A includes GaAs (for example, n-GaAs) of a first conductivity type (for example, n-type). As an example, the first current injection layer 103A is doped with an n-type impurity (for example, Si) at a high concentration (for example, 5×10¹⁸ cm⁻³). The first constituent layer 102-1 of the first reflector 102 is a GaAs-based semiconductor multilayer film reflector (for example, n-GaAs/n-AlGaAs) of a first conductivity type (for example, n-type). The number of pairs of the first constituent layer 102-1 is, for example, two pairs. The first constituent layer 108-1 of the second reflector 108 is a GaAs-based semiconductor multilayer film reflector (for example, p-GaAs/p-AlGaAs) of the second conductivity type (for example, p-type). The number of pairs of the first constituent layer 108-1 is, for example, two pairs. The second current injection layer 103B includes GaAs (for example, p-GaAs) of the second conductivity type (for example, p-type). As an example, the second current injection layer 103B is doped with a p-type impurity (for example, C) at a high concentration (for example, 1×10¹⁹ cm⁻³). The second constituent layer 108-2 of the second reflector 108 is an undoped (i-type) GaAs-based semiconductor multilayer film reflector (for example, i-GaAs/i-AlGaAs). The number of pairs of the second constituent layer 108-2 is, for example, 16 pairs. Note that the second constituent layer 102-2 of the first reflector 102 may be a semiconductor multilayer film reflector of a first conductivity type (for example, n-type). The second constituent layer 108-2 of the second reflector 108 may be a semiconductor multilayer film reflector of the second conductivity type (for example, p-type).

Furthermore, in the surface emitting laser 30, a first mesa M1 including the first constituent layer 102-1 of the first reflector 102, the active layer 106, and the first constituent layer 102-1 of the second reflector 108, and the second current injection layer 103B is formed on the first current injection layer 103A. A second mesa M2 including the second constituent layer 108-2 of the second reflector 108 is formed on the second current injection layer 103B. The first electrode 109 is provided in a frame shape (for example, a ring shape) on a region around the first mesa M1 of the first current injection layer 103A. The second electrode 110 is provided in a frame shape (for example, a ring shape) on a region around the second mesa M2 of the second current injection layer 103B. The height of each of the mesas M1 and M2 is, for example, about 2 μm.

The surface emitting laser 30 can constitute a backside emission type surface emitting laser by making the reflectance of the second reflector 108 slightly higher than the reflectance of the first reflector 102. The surface emitting laser 30 can constitute a surface emission type surface emitting laser by making the reflectance of the first reflector 102 slightly higher than the reflectance of the second reflector 108.

The first current injection layer 103A is provided at least inside the first reflector 102 in a range in which the light intensity is 1/10 times or more and ⅖ times or less the peak intensity. The first current injection layer 103A is preferably disposed in a range in which the light intensity is 1/e² times or more and 1/e times or less the peak intensity.

The second current injection layer 103B is provided at least inside the second reflector 108 in a range in which the light intensity is 1/10 times or more and ⅖ times or less the peak intensity. The second current injection layer 103B is preferably disposed in a range in which the light intensity is 1/e² times or more and 1/e times or less the peak intensity.

Also in the surface emitting laser 30, the number of pairs of each of the first constituent layer 102-1 of the first reflector 102 and the first constituent layer 108-1 of the second reflector 108 is preferably, for example, one to six pairs, more preferably, for example, two to five pairs, and still more preferably two pairs.

The surface layer of the first current injection layer 103A on the side corresponding to the active layer 106 is preferably an etching stop layer including a compound semiconductor containing In (for example, InGaP). The surface layer of the second current injection layer 103B on the side opposite to the side corresponding to the active layer 106 is preferably an etching stop layer including a compound semiconductor containing In (for example, InGaP).

### <<Operation of Surface Emitting Laser>>

Hereinafter, the operation of the surface emitting laser 30 will be briefly described. Here, a case where the surface emitting laser 30 is a backside emission type will be described as an example. In the surface emitting laser 30, for example, the current supplied from the anode side of the laser driver and flowing from the second electrode 110 (anode electrode) is injected into the active layer 106 through the second current injection layer 103B, the first constituent layer 108-1 of the second reflector 108, and the second cladding layer 107 in this order. At this time, the active layer 106 emits light, and the light reciprocates between the first and second reflectors 102 and 108 while being amplified by the active layer 106, and is emitted from the back surface of the substrate 101 as the emitted light EL when the oscillation condition is satisfied. The current that has passed through the active layer 106 reaches the first electrode 109 (cathode electrode) through the first cladding layer 105, the first constituent layer 102-1 of the first reflector 102, and the first current injection layer 103A in this order, and flows out from the first electrode 109 to, for example, the cathode side of the laser driver.

### <<Method for Manufacturing Surface Emitting Laser>>

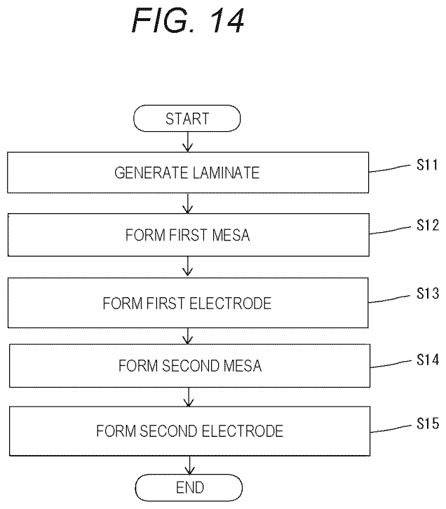

Hereinafter, a method for manufacturing the surface emitting laser 30 will be described with reference to a flowchart of FIG. 14 and the like. Here, as an example, multiple surface emitting lasers 30 are simultaneously generated on one wafer (hereinafter also referred to as a “substrate 101” for convenience) that is a base material of the substrate 101 by a semiconductor manufacturing method using a semiconductor manufacturing apparatus. Next, the multiple continuous and integrated surface emitting lasers 30 are separated from each other to obtain multiple chip-shaped surface emitting lasers 30.

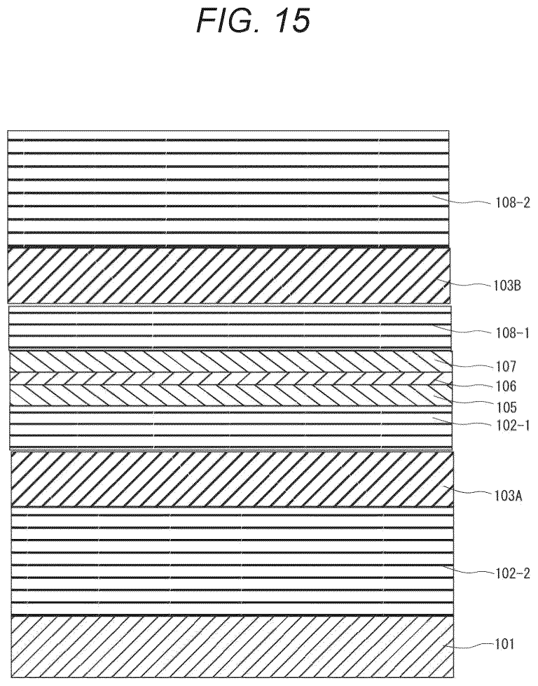

In the first step S11, a laminate is generated (see FIG. 15). Specifically, for example, the second constituent layer 102-2 of the first reflector 102, the first current injection layer 103A, the first constituent layer 102-1 of the first reflector 102, the first cladding layer 105, the active layer 106, the second cladding layer 107, the first constituent layer 108-1 of the second reflector 108, the second current injection layer 103B, and the second constituent layer 108-2 of the second reflector 108 are stacked in this order (for example, epitaxially grown at a growth temperature of 605° C.) on a substrate 101 (for example, an i-GaAs substrate) as a growth substrate by a metal organic chemical vapor deposition (MOCVD) method to generate a laminate. Note that when MOCVD is performed, for example, trimethylgallium ((CH₃)₃Ga) is used as a source gas of gallium, for example, trimethylaluminum ((CH₃)₃Al) is used as a source gas of aluminum, for example, trimethylindium ((CH₃)₃In) is used as a source gas of indium, and for example, trimethylarsine ((CH₃)₃As) is used as a source gas of As. Furthermore, as a source gas of silicon, for example, monosilane (SiH₄) is used, and as a source gas of carbon, for example, carbon tetrabromide (CBr₄) is used.

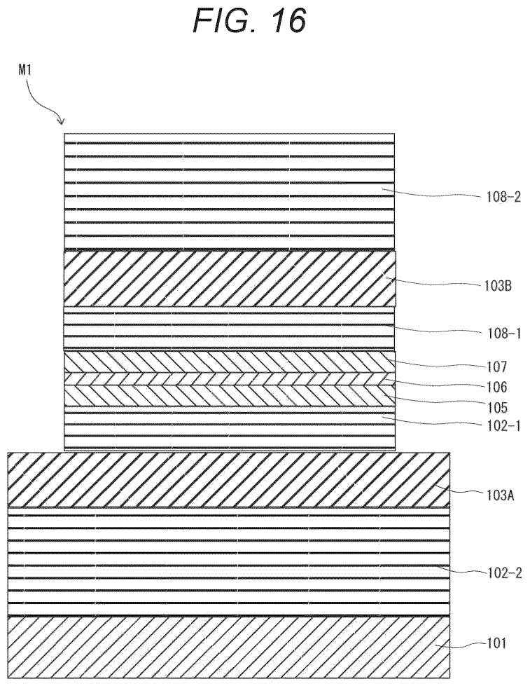

In the next step S12, the first mesa M is formed (see FIG. 16). Specifically, first, a resist pattern is formed by photolithography to cover a portion where the first mesa M1 is to be formed on the surface (upper surface) of the laminate on the side corresponding to the second reflector 108. Next, using the resist pattern as a mask, the laminate is etched by inductively coupled plasma (ICP) dry etching using, for example, Cl₂, SiCl₄, or Ar until the first current injection layer 103A is exposed, and the mesa M1 is formed on the first current injection layer 103A. At this time, if the surface layer of the first current injection layer 103A on the side corresponding to the active layer 106 is an etching stop layer (for example, InGaP), the etching of the first current injection layer 103A can be more reliably suppressed. Thereafter, the resist pattern is removed.

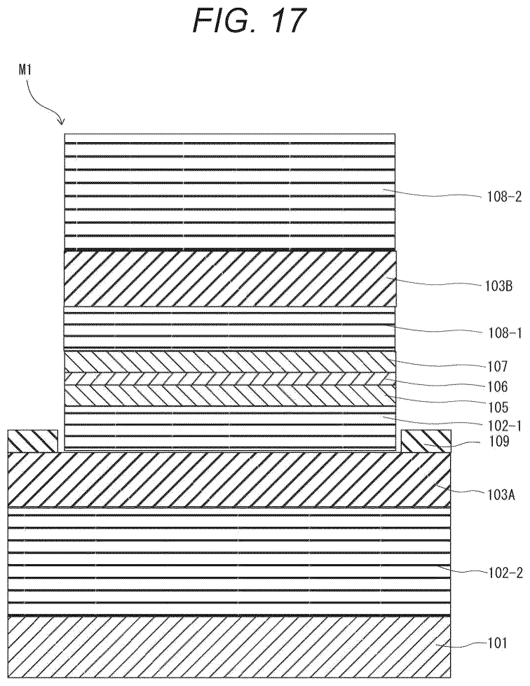

In the next step S13, the first electrode 109 is formed (see FIG. 17). Specifically, for example, using a lift-off method, the first electrode 109 is formed in a frame shape (for example, a ring shape) on a region around the first mesa M1 of the first current injection layer 103A so as to surround the first mesa M1. At this time, vacuum deposition, sputtering, or the like is used to form a film of the electrode material of the first electrode 109.

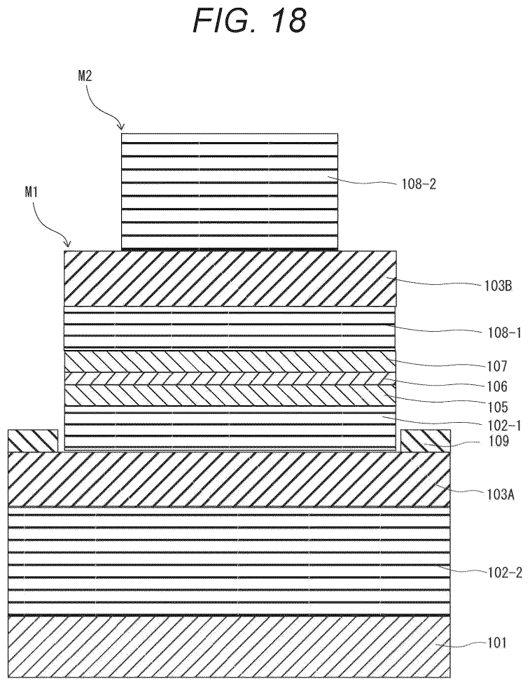

In the next step S14, a second mesa M is formed (see FIG. 18). Specifically, first, a resist pattern is formed by photolithography to cover a portion where the second mesa M2 is to be formed on the surface (upper surface) of the laminate on the side corresponding to the second reflector 108. Next, using the resist pattern as a mask, the laminate is etched by inductively coupled plasma (ICP) dry etching using, for example, Cl₂, SiCl₄, or Ar until the second current injection layer 103B is exposed, and the second mesa M2 is formed on the second current injection layer 103B. At this time, if the surface layer of the second current injection layer 103B on the side opposite to the side corresponding to the active layer 106 is an etching stop layer (for example, InGaP), the etching of the second current injection layer 103B can be more reliably suppressed. Thereafter, the resist pattern is removed.

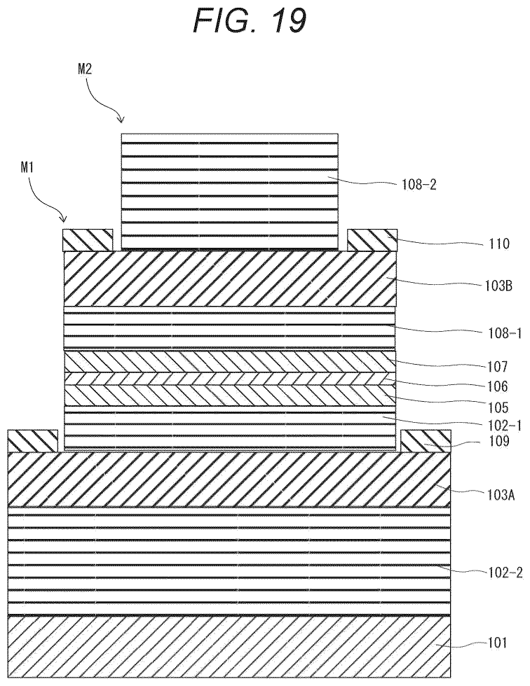

In the final step S15, the second electrode 110 is formed (see FIG. 19). Specifically, for example, using a lift-off method, the second electrode 110 is formed in a frame shape (for example, a ring shape) so as to surround the second mesa M2 on a region around the second mesa M2 of the second current injection layer 103B. At this time, vacuum deposition, sputtering, or the like is used to form a film of the electrode material of the second electrode 110.

### <<Effects of Surface Emitting Laser>>

According to the surface emitting laser 30, since the current injection layers 103 A and 103B are provided at least inside the first reflectors 102 and 108, respectively, series resistance can be further reduced, and current injection efficiency into the active layer 106 can be further improved.

### 4. Surface Emitting Laser According to Fourth Embodiment of Present Technology

### <<Configuration of Surface Emitting Laser>>

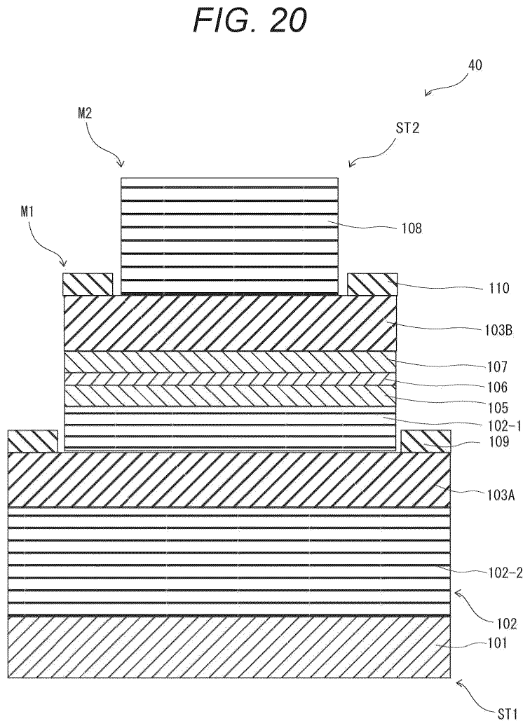

FIG. 20 is a cross-sectional view of a surface emitting laser 40 according to a fourth embodiment of the present technology. The surface emitting laser 40 has a configuration substantially similar to that of the surface emitting laser 30 according to the third embodiment except that the second current injection layer 103B (another current injection layer) is provided between the active layer 106 and the second reflector 108.

In the surface emitting laser 40, the second current injection layer 103B is disposed between the second cladding layer 107 and the second reflector 108. Here, the position of the second current injection layer 103B in the layering direction depends on the thickness of the second cladding layer 107.

Also in the surface emitting laser 40, the first current injection layer 103A is provided at least inside the first reflector 102 in a range in which the light intensity is 1/10 times or more and ⅖ times or less the peak intensity. The first current injection layer 103A is preferably disposed in a range in which the light intensity is 1/e² times or more and 1/e times or less the peak intensity.

In the surface emitting laser 40, the second current injection layer 103B is preferably provided in a range in which the light intensity is 1/10 times or more and ⅖ times or less the peak intensity. The second current injection layer 103B is more preferably disposed in a range in which the light intensity is 1/e² times or more and 1/e times or less the peak intensity.

The surface layer of the first current injection layer 103A on the side corresponding to the active layer 106 is preferably an etching stop layer including a compound semiconductor containing In (for example, InGaP). The surface layer of the second current injection layer 103B on the side opposite to the side corresponding to the active layer 106 is preferably an etching stop layer including a compound semiconductor containing In (for example, InGaP).

### <<Operation of Surface Emitting Laser>>

Hereinafter, the operation of the surface emitting laser 40 will be briefly described. Here, a case where the surface emitting laser 40 is a backside emission type will be described as an example. In the surface emitting laser 40, for example, the current supplied from the anode side of the laser driver and flowing from the second electrode 110 (anode electrode) is injected into the active layer 106 through the second current injection layer 103B and the second cladding layer 107 in this order. At this time, the active layer 106 emits light, and the light reciprocates between the first and second reflectors 102 and 108 while being amplified by the active layer 106, and is emitted from the back surface of the substrate 101 as the emitted light EL when the oscillation condition is satisfied. The current that has passed through the active layer 106 reaches the first electrode 109 (cathode electrode) through the first cladding layer 105, the first constituent layer 102-1 of the first reflector 102, and the first current injection layer 103A in this order, and flows out from the first electrode 109 to, for example, the cathode side of the laser driver.

### <<Method for Manufacturing Surface Emitting Laser>>

The surface emitting laser 40 can be manufactured by a manufacturing method according to the method for manufacturing the surface emitting laser 30 according to the third embodiment.

According to the surface emitting laser 40, it is possible to obtain effects substantially similar to those of the surface emitting laser 30 according to the third embodiment.

### 5. Surface Emitting Laser According to Fifth Embodiment of Present Technology

### <<Configuration of Surface Emitting Laser>>

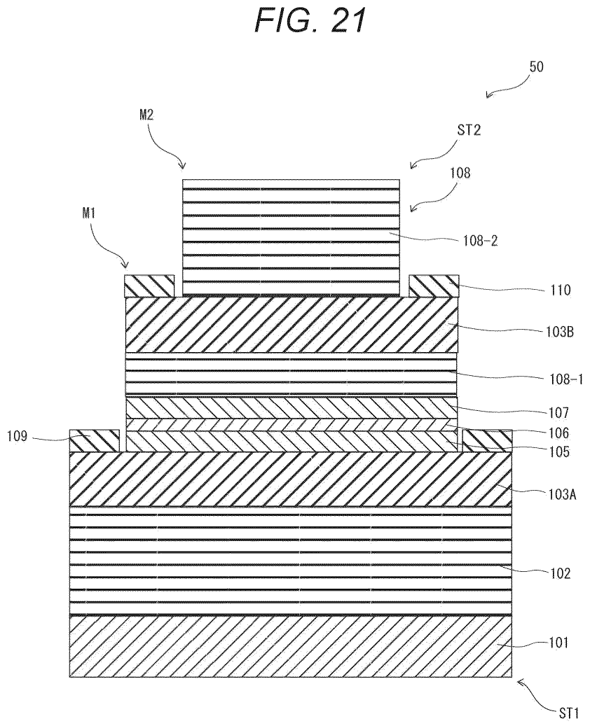

FIG. 21 is a cross-sectional view of a surface emitting laser 50 according to a fifth embodiment of the present technology. £ The surface emitting laser 50 has a configuration substantially similar to that of the surface emitting laser 30 according to the third embodiment except that a first current injection layer 103A (another current injection layer) is provided between the active layer 106 and the first reflector 102.

In the surface emitting laser 50, the first current injection layer 103A is disposed between the first cladding layer 105 and the first reflector 102. Here, the position of the first current injection layer 103A in the layering direction depends on the thickness of the first cladding layer 105.

In the surface emitting laser 50, the first current injection layer 103A is preferably provided in a range in which the light intensity is 1/10 times or more and ⅖ times or less the peak intensity. The first current injection layer 103A is more preferably disposed in a range in which the light intensity is 1/e² times or more and 1/e times or less the peak intensity.

Also in the surface emitting laser 50, the second current injection layer 103B is provided at least inside of the second reflector 108 in a range in which the light intensity is 1/10 times or more and ⅖ times or less the peak intensity. The second current injection layer 103B is preferably disposed in a range in which the light intensity is 1/e² times or more and 1/e times or less the peak intensity.

The surface layer of the first current injection layer 103A on the side corresponding to the active layer 106 is preferably an etching stop layer including a compound semiconductor containing In (for example, InGaP). The surface layer of the second current injection layer 103B on the side opposite to the side corresponding to the active layer 106 is preferably an etching stop layer including a compound semiconductor containing In (for example, InGaP).

### <<Operation of Surface Emitting Laser>>

Hereinafter, the operation of the surface emitting laser 50 will be described. Here, a case where the surface emitting laser 50 is a backside emission type will be described as an example. In the surface emitting laser 50, for example, the current supplied from the anode side of the laser driver and flowing from the second electrode 110 (anode electrode) is injected into the active layer 106 through the second current injection layer 103B, the first constituent layer 108-1 of the second reflector 108, and the second cladding layer 107 in this order. At this time, the active layer 106 emits light, and the light reciprocates between the first and second reflectors 102 and 108 while being amplified by the active layer 106, and is emitted from the back surface of the substrate 101 as the emitted light EL when the oscillation condition is satisfied. The current that has passed through the active layer 106 reaches the first electrode 109 (cathode electrode) through the first cladding layer 105 and the first current injection layer 103A in this order, and flows out from the first electrode 109 to, for example, the cathode side of the laser driver.

### <<Method for Manufacturing Surface Emitting Laser>>

The surface emitting laser 50 can be manufactured by a manufacturing method according to the manufacturing method of the surface emitting laser 30 of the third embodiment.

According to the surface emitting laser 50, it is possible to obtain effects substantially similar to those of the surface emitting laser 30 according to the third embodiment.

### 6. Modification of Present Technology

The present technology is not limited to the embodiments described above, and various modifications can be made.

### (Surface Emitting Laser According to Modification 1 of First Embodiment of Present Technology)

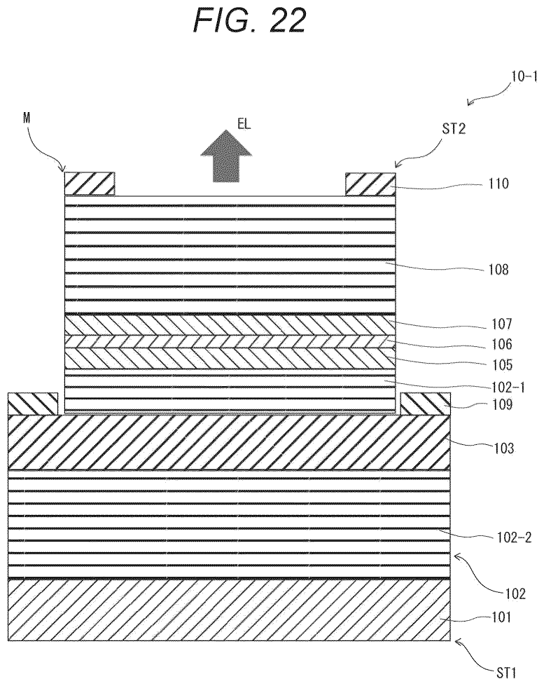

A surface emitting laser 10-1 according to Modification 1 of the first embodiment illustrated in FIG. 22 has a configuration similar to that of the surface emitting laser 10 according to the first embodiment except that the second electrode 110 has a frame shape (for example, a ring shape) and emits emitted light EL from the upper surface of the second reflector 108. According to the surface emitting laser 10-1, it is possible to provide a surface emitting laser of a surface emission type having a similar effect as the surface emitting laser 10 according to the first embodiment.

### (Surface Emitting Laser According to Modification 2 of First Embodiment of Present Technology)

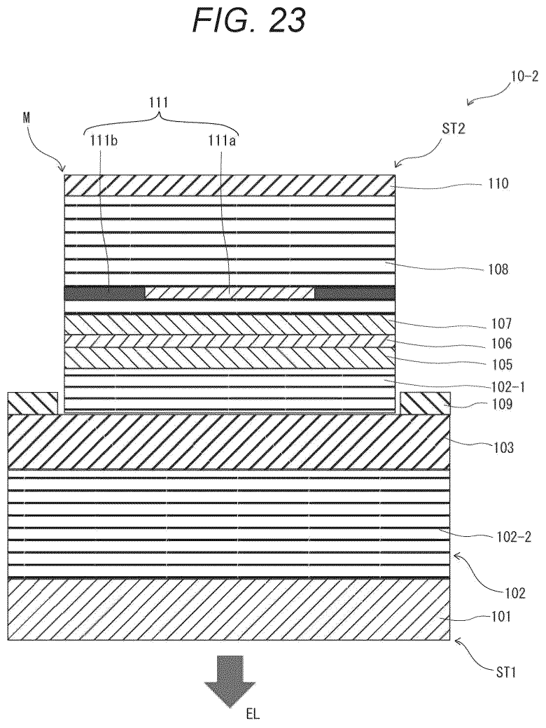

A surface emitting laser 10-2 according to Modification 2 of the first embodiment illustrated in FIG. 23 has a configuration similar to that of the surface emitting laser 10 according to the first embodiment except that an oxide confinement layer 111 is provided inside the second reflector 108. The oxide confinement layer 111 includes a non-oxidized region 111a (for example, an AlAs layer) and an oxidized region 111b (for example, an Al₂O₃ layer) surrounding the non-oxidized region 11la. The oxide confinement layer 111 functions as a current/light confinement layer. The oxide confinement layer 111 may be provided at another position in the resonator. According to the surface emitting laser 10-2, it is possible to provide a backside emission type surface emitting laser having a current/light confinement function while achieving a similar effect as the surface emitting laser 10 according to the first embodiment.

### (Surface Emitting Laser According to Modification 3 of First Embodiment of Present Technology)

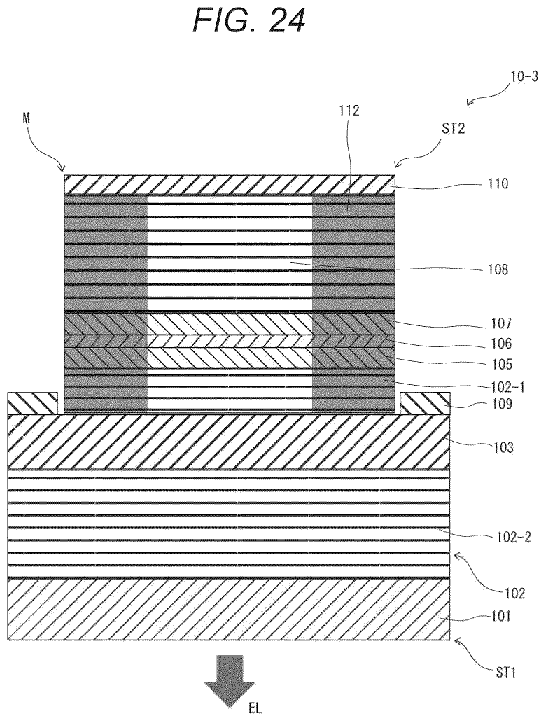

A surface emitting laser 10-3 according to Modification 3 of the first embodiment illustrated in FIG. 24 has a configuration similar to that of the surface emitting laser 10 according to the first embodiment except that an ion-implanted region 112 is formed at least in a peripheral portion of the second reflector 108 (for example, a peripheral portion of the second reflector 108, the second cladding layer 107, the first active layer 106, and the first cladding layer 105). Examples of the ion species used for the ion-implanted region 112 include H⁺ and B⁺. The ion-implanted region 112 functions as a current confinement layer. According to the surface emitting laser 10-3, it is possible to provide a backside emission type surface emitting laser having a current confinement function while achieving a similar effect as the surface emitting laser 10 according to the first embodiment.

### (Surface Emitting Laser According to Modification 4 of First Embodiment of Present Technology)

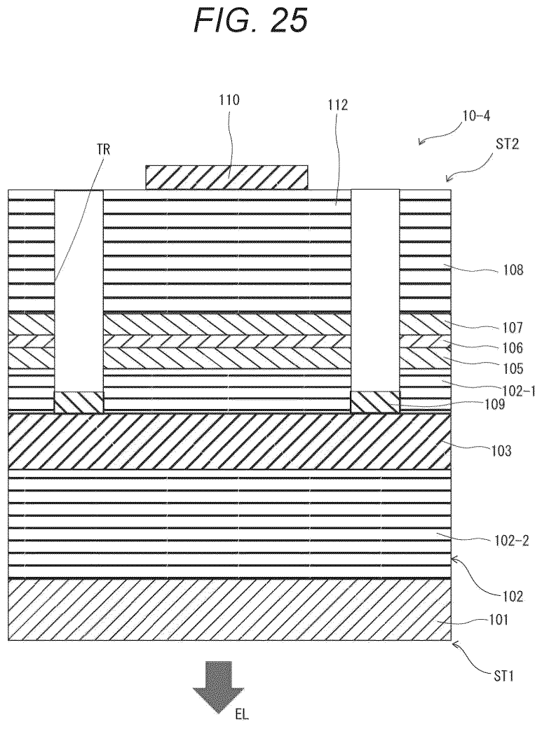

A surface emitting laser 10-4 according to Modification 4 of the first embodiment illustrated in FIG. 25 has a configuration substantially similar to that of the surface emitting laser 10 according to the first embodiment except that a trench TR having a frame shape in plan view (for example, a ring shape in plan view) is formed instead of a mesa. The bottom surface of the trench TR is the upper surface of the current injection layer 103. The first electrode 109 is provided on the bottom surface of the trench TR. According to the surface emitting laser 10-4, it is possible to provide a backside emission type surface emitting laser having a structure without a mesa that exhibits a similar effect as the surface emitting laser 10 according to the first embodiment.

### (Surface Emitting Laser According to Modification 5 of First Embodiment of Present Technology)

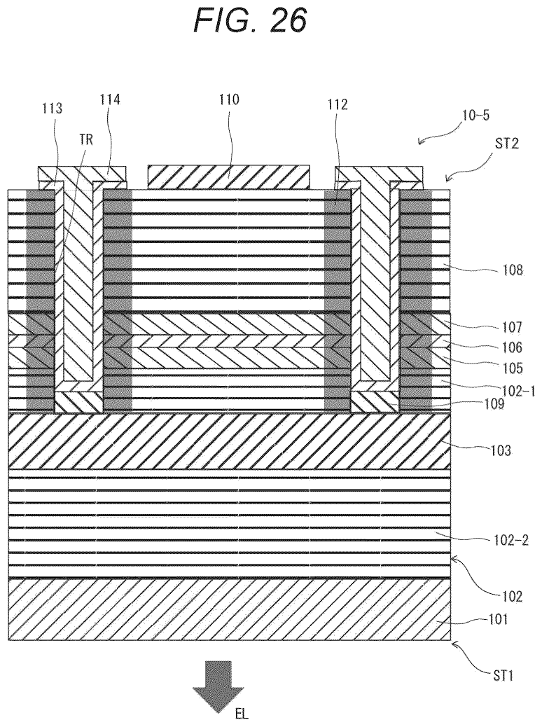

A surface emitting laser 10-5 according to Modification 5 of the first embodiment illustrated in FIG. 26 has a configuration similar to that of the surface emitting laser 10-4 according to Modification 4 except that wiring in which a pad metal 113 and a plating metal 114 are stacked is provided in a trench TR. The pad metal 113 extends along the wall surface of the trench TR, and has one end in contact with the first electrode 109 and the other end exposed to the upper surface of the second reflector 108. The plating metal 114 is provided so as to fill a groove surrounded by the pad metal 113 in the trench TR. An ion-implanted region 112 is provided around the trench TR. The ion-implanted region 112 has both a function of insulating the second structure ST2 and the active layer 106 from the wiring described above and a current confinement function. Note that the wiring described above may include only the pad metal 113 provided in a thick film, for example. According to the surface emitting laser 10-5, similar effects as those of the surface emitting laser 10 according to the first embodiment are obtained, and it is possible to realize a backside emission type surface emitting laser suitable for flip-chip (junction-down) mounting on a laser driver, for example.

### (Surface Emitting Laser According to Modification 6 of First Embodiment of Present Technology)

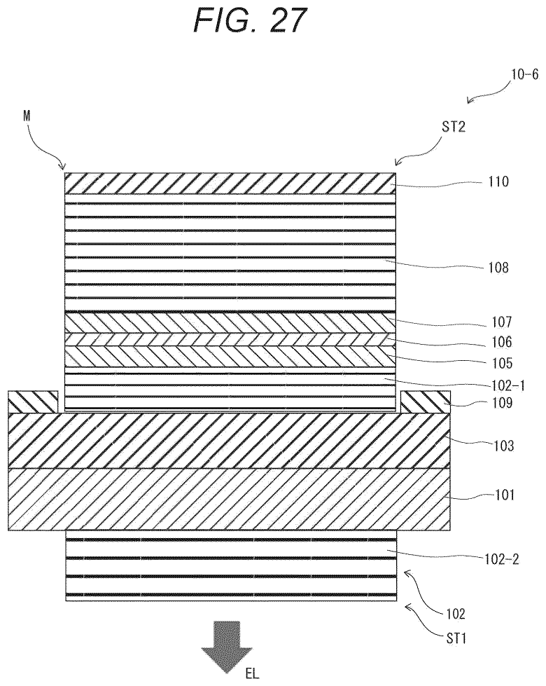

A surface emitting laser 10-6 according to Modification 6 of the first embodiment illustrated in FIG. 27 has a configuration substantially similar to that of the surface emitting laser 10 according to the first embodiment except that the second constituent layer 102-2 of the first reflector 102 is a dielectric multilayer film reflector. In the surface emitting laser 10-6, a dielectric multilayer film reflector as the second constituent layer 102-2 is provided on the back surface of the substrate 101. The material of the dielectric multilayer film reflector is, for example, TiO₂/SiO₂. The dielectric multilayer film reflector can obtain high reflectance with a small number of pairs. According to the surface emitting laser 10-6, it is possible to provide a thin backside emission type surface emitting laser that exhibits a similar effect as the surface emitting laser 10 according to the first embodiment.

### (Surface Emitting Laser According to Modification 7 of First Embodiment of Present Technology)

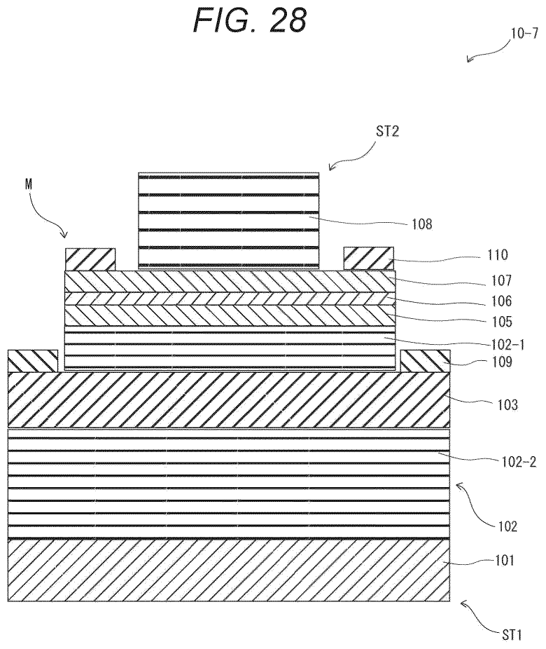

A surface emitting laser 10-7 according to Modification 7 of the first embodiment illustrated in FIG. 28 has a configuration substantially similar to that of the surface emitting laser 10 according to the first embodiment except that the second reflector 108 is a dielectric multilayer film reflector. In the surface emitting laser 10-7, a dielectric multilayer film reflector as the second reflector 108 is provided in a mesa shape on the upper surface of the second cladding layer 107. The material of the dielectric multilayer film reflector is, for example, TiO₂/SiO₂. According to the surface emitting laser 10-7, it is possible to provide a thin surface emitting laser of a backside emission type or a surface emission type that exhibits a similar effect as the surface emitting laser 10 according to the first embodiment.

### (Surface Emitting Laser According to Modification 8 of First Embodiment of Present Technology)

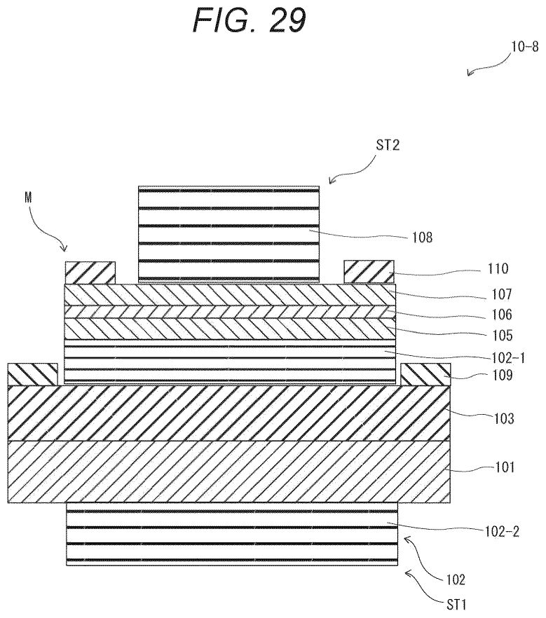

A surface emitting laser 10-8 according to Modification 8 of the first embodiment illustrated in FIG. 29 has a configuration substantially similar to that of the surface emitting laser 10 according to the first embodiment except that both the second constituent layer 102-2 of the first reflector 102 and the second reflector 108 are dielectric multilayer film reflectors. In the surface emitting laser 10-8, the dielectric multilayer film reflector as the second constituent layer 102-2 is provided on the back surface of the substrate 101, and the dielectric multilayer film reflector as the second reflector 108 is provided in a mesa shape on the upper surface of the second cladding layer 107. The material of each dielectric multilayer film reflector is, for example, TiO₂/SiO₂. According to the surface emitting laser 10-8, it is possible to provide an ultra-thin surface emitting laser of a backside emission type or a surface emission type that exhibits a similar effect as the surface emitting laser 10 according to the first embodiment.

### (Surface Emitting Laser According to Modification 9 of First Embodiment of Present Technology)

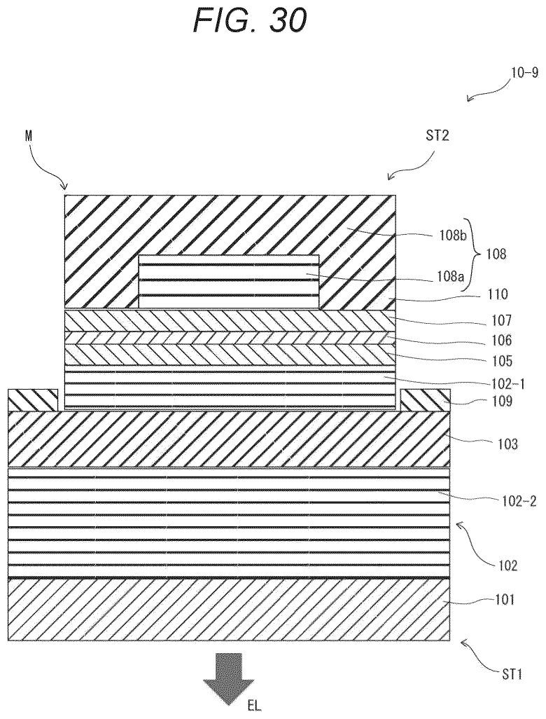

A surface emitting laser 10-9 according to Modification 9 of the first embodiment illustrated in FIG. 30 has a configuration substantially similar to that of the surface emitting laser 10 according to the first embodiment except that the second reflector 108 is a hybrid mirror including a dielectric multilayer film reflector 108a and a metal reflector 108b and does not have the second electrode 110. In the surface emitting laser 10-9, the dielectric multilayer film reflector 108a of the second reflector 108 is provided in a mesa shape on the upper surface of the second cladding layer 107, and the metal reflector 108b is provided so as to cover the peripheral portions of the upper surfaces of the dielectric multilayer film reflector 108a and the second cladding layer 107. The material of the dielectric multilayer film reflector is, for example, TiO₂/SiO₂. The metal reflector 108b includes, for example, a metal such as Au, Ag, or Al, and has the function of the second electrode 110 and the heat dissipation function. According to the surface emitting laser 10-9, it is possible to provide a high output and high heat dissipation backside emission type surface emitting laser having a similar effect as the surface emitting laser 10 according to the first embodiment.

### (Surface Emitting Laser According to Modification 1 of Second Embodiment of Present Technology)

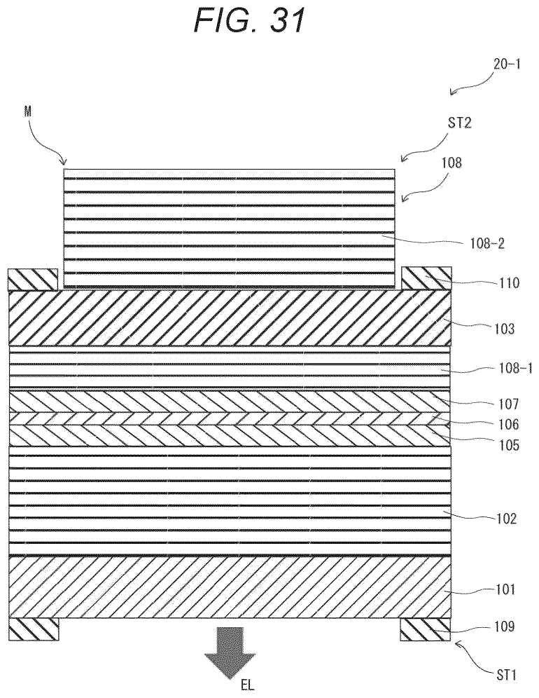

A surface emitting laser 20-1 according to Modification 1 of the second embodiment illustrated in FIG. 31 has a configuration substantially similar to that of the surface emitting laser 20 according to the second embodiment except that it is a backside emission type surface emitting laser. In the surface emitting laser 20-1, the first electrode 109 is provided in a frame shape (for example, a ring shape) on the back surface of the substrate 101. According to the surface emitting laser 20-1, it is possible to provide a backside emission type surface emitting laser that exhibits a similar effect as the surface emitting laser 20 according to the second embodiment.

### (Surface Emitting Laser According to Modification 2 of Second Embodiment of Present Technology)

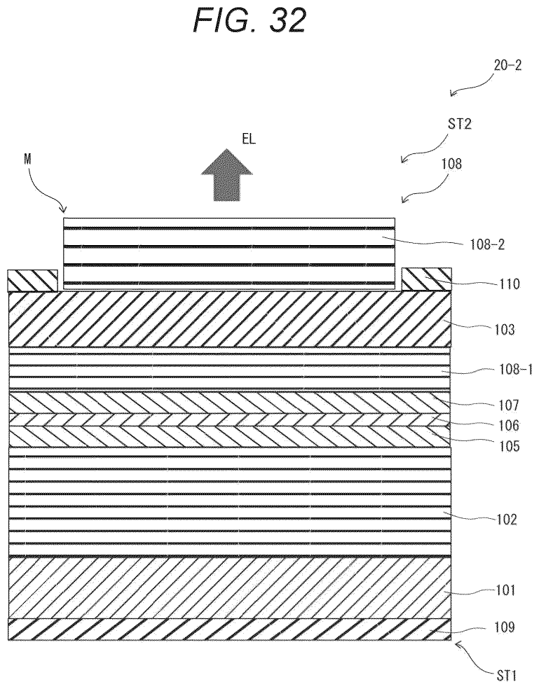

A surface emitting laser 20-2 according to Modification 2 of the second embodiment illustrated in FIG. 32 has a configuration similar to that of the surface emitting laser 20 according to the second embodiment except that the second constituent layer 108-2 of the second reflector 108 is a dielectric multilayer film reflector. In the surface emitting laser 20-2, a dielectric multilayer film reflector as the second constituent layer 108-2 is provided in a mesa shape on the upper surface of the current injection layer 103. The material of the dielectric multilayer film reflector is, for example, TiO₂/SiO₂. According to the surface emitting laser 20-2, it is possible to provide a thin backside emission type surface emitting laser that exhibits a similar effect as the surface emitting laser 20 according to the second embodiment.

### (Surface Emitting Laser According to Modification of Third Embodiment of Present Technology)

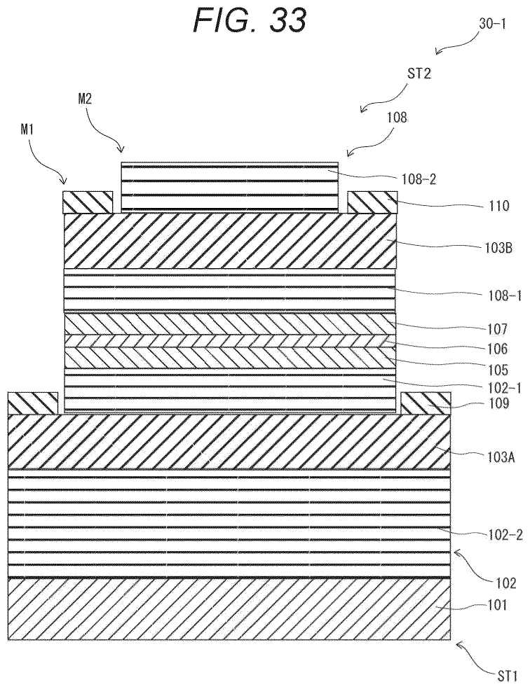

A surface emitting laser 30-1 according to a modification of the third embodiment illustrated in FIG. 33 has a configuration similar to that of the surface emitting laser 30 according to the third embodiment except that the second constituent layer 108-2 of the second reflector 108 is a dielectric multilayer film reflector. In the surface emitting laser 30-1, a dielectric multilayer film reflector as the second constituent layer 108-2 is provided in a mesa shape on the upper surface of the second current injection layer 103B. The material of the dielectric multilayer film reflector is, for example, TiO₂/SiO₂. According to the surface emitting laser 30-1, it is possible to provide a thin surface emitting laser of a backside emission type or a surface emission type that exhibits a similar effect as the surface emitting laser 30 according to the third embodiment.

### (Surface Emitting Laser According to Modification of Fourth Embodiment of Present Technology)

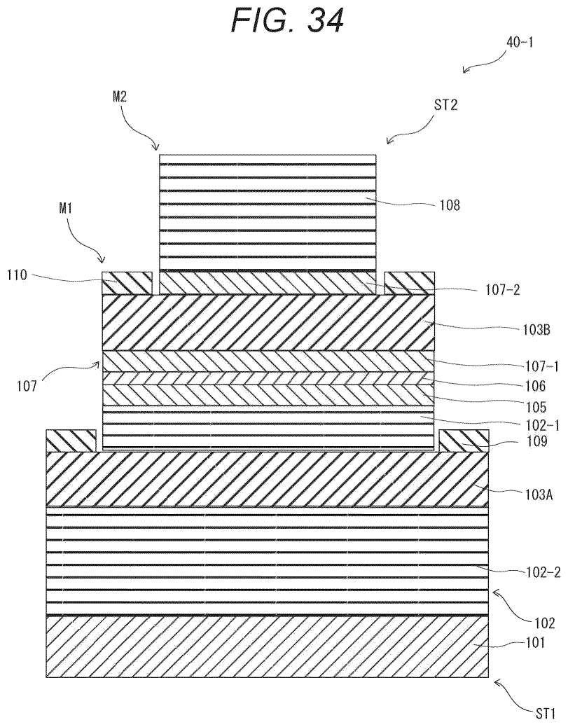

A surface emitting laser 40-1 according to a modification of the fourth embodiment illustrated in FIG. 34 has a configuration substantially similar to that of the surface emitting laser 40 according to the fourth embodiment except that the second current injection layer 103B is provided at least inside the second cladding layer 107. In the surface emitting laser 40-1, the second cladding layer 107 includes the first and second constituent layers 107-1 and 107-2 in this order from the side corresponding to the active layer 106. The second current injection layer 103B is disposed between the first and second constituent layers 107-1 and 107-2. In the surface emitting laser 40-1, the first constituent layer 102-1 of the first reflector 102, the first cladding layer 105, the active layer 106, the first constituent layer 107-1 of the second cladding layer 107, and the second current injection layer 103B constitute a mesa M1, and the second constituent layer 107-2 of the second cladding layer 107 and the second reflector 108 constitute a second mesa M2. According to the surface emitting laser 40-1, it is possible to provide a surface emitting laser of a backside emission type and a surface emission type that exhibits a similar effect as the surface emitting laser 40 according to the fourth embodiment.

### (Surface Emitting Laser According to Modification of Fifth Embodiment of Present Technology)

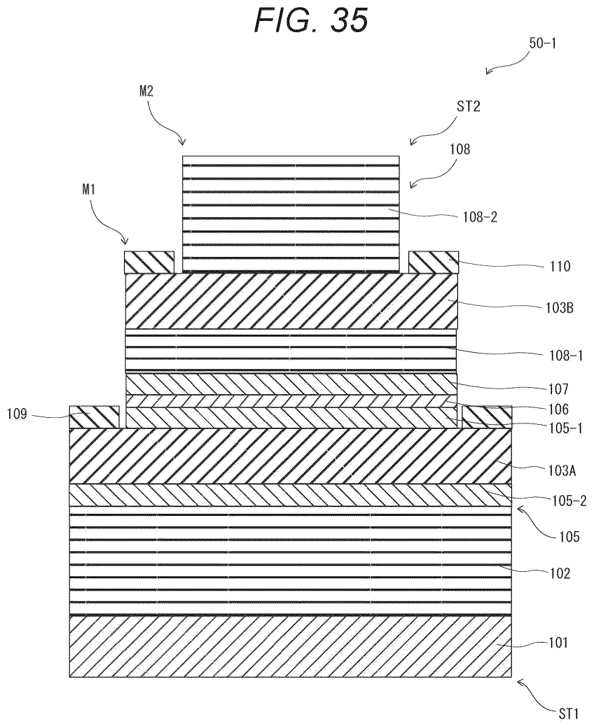

A surface emitting laser 50-1 according to a modification of the fifth embodiment illustrated in FIG. 35 has a configuration substantially similar to that of the surface emitting laser 50 according to the fifth embodiment except that the first current injection layer 103A is provided at least inside the first cladding layer 105. In the surface emitting laser 50-1, the first cladding layer 105 includes first and second constituent layers 105-1 and 105-2 in this order from the side corresponding to the active layer 106. The first current injection layer 103A is disposed between the first and second constituent layers 105-1 and 105-2. In the surface emitting laser 50-1, the first constituent layer 105-1 of the first cladding layer 105, the active layer 106, the second cladding layer 107, the first constituent layer 108-1 of the second reflector 108, and the second current injection layer 103B constitute a mesa M1, and the second constituent layer 108-2 of the second reflector 108 constitutes a second mesa M2.

### (Other Modifications of the Present Technology)

For example, the current confinement in the surface emitting laser is not limited to the current confinement by the oxide confinement layer or the ion-implanted region. For example, current confinement may be performed by a QWI that provides a bandgap energy difference between the inside and outside of the aperture by Ga hole diffusion to confine carriers, a buried tunnel junction, or the like.

For example, the optical confinement in the surface emitting laser is not limited to that by the oxide confinement layer. For example, like a structure in which a central portion of an intermediate structure including the active layer 106 such as a buried tunnel junction is surrounded by a high resistance region or an insulating region, a refractive index difference is generated between the central portion and the peripheral portion of the intermediate structure, and light confinement can be performed in the entire structure in which light is confined in the central portion.

For example, at least one of the first and second reflectors of the surface emitting laser may include multiple constituent layers including different materials and stacked on each other. Specifically, the first and second reflectors may be a hybrid mirror including a semiconductor multilayer film reflector and a dielectric multilayer film reflector, a hybrid mirror including a semiconductor multilayer film reflector and a metal reflector, a hybrid mirror including a dielectric multilayer film reflector and a metal reflector, or a hybrid mirror including a semiconductor multilayer film reflector, a dielectric multilayer film reflector, and a metal reflector.

For example, the substrate 101 may be a Si substrate, a Ge substrate, a GaN substrate, an InP substrate, or the like. In any case, the semiconductor layer stacked on the substrate 101 is preferably appropriately selected so as to be lattice-matched with the material of the substrate 101. For the surface emitting laser, a material having any oscillation wavelength included in the wavelength band of 200 to 2000 nm can be used.

The conductivity types (n-type and p-type) of the first and second structures ST1 and ST2 of the surface emitting lasers of the above embodiments and modifications may be interchanged.

Some of the configurations of the surface emitting lasers of the embodiments and modifications described above may be combined within a range in which they do not contradict each other.

In each embodiment and each modification described above, the material, conductivity type, thickness, width, numerical value, shape, size, and the like of each layer constituting the surface emitting laser can be appropriately changed within a range functioning as the surface emitting laser.

### 7. Application Examples to Electronic Device

The technology according to the present disclosure (the present technology) can be applied to various products (electronic devices). For example, the technology according to the present disclosure may be realized as any type of mobile body such as an automobile, an electric vehicle, a hybrid electric vehicle, a motorcycle, a bicycle, a personal mobility, an airplane, a drone, a ship, or a robot, or as an apparatus mounted on a low power consumption device (for example, a smartphone, a smartwatch, a mouse, or the like).

The surface emitting laser according to the present technology can also be applied as, for example, a light source of a device that forms or displays an image by laser light (for example, a laser printer, a laser copier, a projector, a head-mounted display, a head-up display, or the like).

### 8. Example in Which Surface Emitting Laser is Applied to Distance Measuring Device

Hereinafter, application examples of the surface emitting laser according to each of the embodiments and modifications described above will be described.

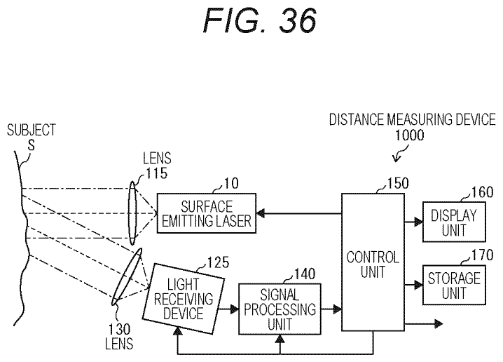

FIG. 36 illustrates an example of a schematic configuration of a distance measuring device 1000 including the surface emitting laser 10 as an example of an electronic device according to the present technology. The distance measuring device 1000 measures the distance to a subject S by a time of flight (TOF) method. The distance measuring device 1000 includes the surface emitting laser 10 as a light source. The distance measuring device 1000 includes, for example, a surface emitting laser 10, a light receiving device 125, lenses 115 and 130, a signal processing unit 140, a control unit 150, a display unit 160, and a storage unit 170.

The light receiving device 125 detects light reflected by a subject S. The lens 115 is a lens for collimating the light emitted from the surface emitting laser 10, and is a collimating lens. The lens 130 is a condenser lens that collects the light reflected by the subject S and guides the light to the light receiving device 125.

The signal processing unit 140 is a circuit for generating a signal corresponding to a difference between a signal input from the light receiving device 125 and a reference signal input from the control unit 150. The control unit 150 includes, for example, a time to digital converter (TDC). The reference signal may be a signal input from the control unit 150, or may be an output signal of a detection unit that directly detects the output of the surface emitting laser 10. The control unit 150 is, for example, a processor that controls the surface emitting laser 10, the light receiving device 125, the signal processing unit 140, the display unit 160, and the storage unit 170. The control unit 150 is a circuit that measures a distance to the subject S on the basis of a signal generated by the signal processing unit 140. The control unit 150 generates a video signal for displaying information about the distance to the subject S, and outputs the video signal to the display unit 160. The display unit 160 displays the information regarding the distance to the subject S on the basis of the video signal input from the control unit 150. The control unit 150 stores information about the distance to the subject S in the storage unit 170.

In the present application example, instead of the surface emitting laser 10, any one of the surface emitting lasers 10-1 to 10-9, 20, 20-1, 20-2, 30, 30-1, 40, 40-1, 50, or 50-1 described above can be applied to the distance measuring device 1000.

### 9. Example in Which Distance Measuring Device is Mounted on Mobile Body

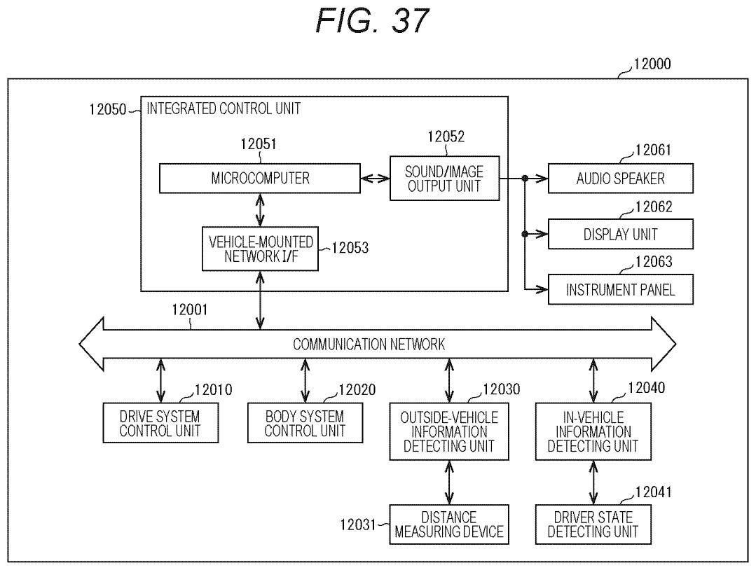

FIG. 37 is a block diagram illustrating a schematic configuration example of a vehicle control system that is an example of a mobile body control system to which the technology according to the present disclosure can be applied.

The vehicle control system 12000 includes multiple electronic control units connected to each other via a communication network 12001. In the example illustrated in FIG. 37, the vehicle control system 12000 includes a drive system control unit 12010, a body system control unit 12020, an outside-vehicle information detecting unit 12030, an in-vehicle information detecting unit 12040, and an integrated control unit 12050. Furthermore, a microcomputer 12051, a sound/image output unit 12052, and a vehicle-mounted network interface (I/F) 12053 are illustrated as a functional configuration of the integrated control unit 12050.

The drive system control unit 12010 controls the operation of devices related to the drive system of the vehicle in accordance with various types of programs. For example, the drive system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various types of devices provided to a vehicle body in accordance with various types of programs. For example, the body system control unit 12020 functions as a control device for a keyless entry system, a smart key system, a power window device, or various types of lamps such as a headlamp, a backup lamp, a brake lamp, a turn signal, a fog lamp, or the like. In this case, radio waves transmitted from a mobile device as an alternative to a key or signals of various types of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, a distance measuring device 12031 is connected to the outside-vehicle information detecting unit 12030. The distance measuring device 12031 includes the distance measuring device 1000 described above. The outside-vehicle information detecting unit 12030 causes the distance measuring device 12031 to measure a distance to an object (subject S) outside the vehicle, and acquires distance data acquired by the measurement. The outside-vehicle information detecting unit 12030 may perform object detection processing of a person, a car, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting unit 12041 that detects the state of a driver. The driver state detecting unit 12041, for example, includes a camera that images the driver. On the basis of detection information input from the driver state detecting unit 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the drive system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output unit 12052 transmits an output signal of at least one of a sound and an image to an output device capable of visually or auditorily notifying information to an occupant of the vehicle or the outside of the vehicle. In the example of FIG. 37, an audio speaker 12061, a display unit 12062, and an instrument panel 12063 are illustrated as output devices. The display unit 12062 may, for example, include at least one of an on-board display and a head-up display.

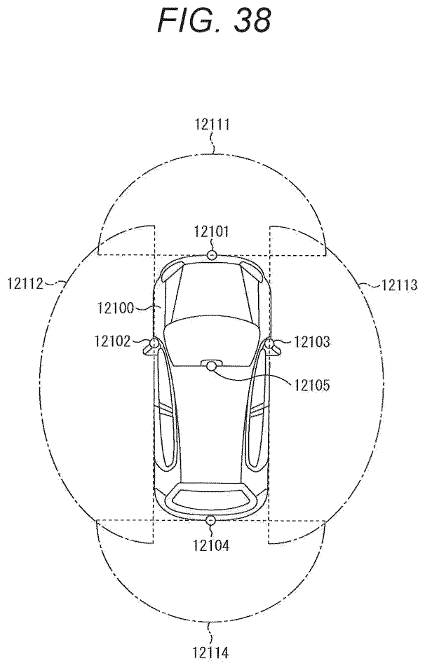

FIG. 38 is a diagram illustrating an example of installation positions of the distance measuring device 12031.

In FIG. 38, a vehicle 12100 includes distance measuring devices 12101, 12102, 12103, 12104, and 12105 as the distance measuring device 12031.

For example, the distance measuring devices 12101, 12102, 12103, 12104, and 12105 are provided at positions such as a front nose, sideview mirrors, a rear bumper, a back door, an upper portion of a windshield in a vehicle interior, and the like of the vehicle 12100. The distance measuring device 12101 provided at the front nose and the distance measuring device 12105 provided at the upper portion of the windshield in the vehicle interior mainly acquire data of the front side of the vehicle 12100. The distance measuring devices 12102 and 12103 provided at the sideview mirrors mainly acquire data of the sides of the vehicle 12100. The distance measuring device 12104 provided at the rear bumper or the back door mainly acquires data of the rear side of the vehicle 12100. The data of the front side acquired by the distance measuring devices 12101 and 12105 is mainly used to detect a preceding vehicle, a pedestrian, an obstacle, a traffic light, a traffic sign, or the like.

Note that FIG. 38 illustrates an example of detection ranges of the distance measuring devices 12101 to 12104. A detection range 12111 indicates a detection range of the distance measuring device 12101 provided at the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided at the rear bumper or the back door.

For example, the microcomputer 12051 may obtain a distance to each three-dimensional object within the detection ranges 12111 to 12114 and a temporal change in the distance (relative speed with respect to the vehicle 12100) on the basis of the distance data obtained from the distance measuring devices 12101 to 12104, whereby particularly a nearest three-dimensional object present on a traveling path of the vehicle 12100, which travels in substantially the same direction as the vehicle 12100 at a predetermined speed (for example, equal to or more than 0 km/h), may be extracted as a preceding vehicle. Further, the microcomputer 12051 can set a following distance to be maintained in front of a preceding vehicle in advance, and perform automatic brake control (including follow-up stop control), automatic acceleration control (including follow-up start control), or the like. It is thus possible to perform cooperative control intended for automated driving that makes the vehicle travel automatedly without depending on the operation of the driver or the like.

For example, on the basis of the distance data obtained from the distance measuring devices 12101 to 12104, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display unit 12062, and performs forced deceleration or avoidance steering via the drive system control unit 12010. The microcomputer 12051 can thereby assist in driving to avoid collision.

An example of the mobile body control system to which the technology according to the present disclosure can be applied has been described above. The technology according to the present disclosure may be applied to the distance measuring device 12031 among the configurations described above.

Furthermore, the present technology may also adopt the following configurations.
(1) A surface emitting laser including:
a first structure including a first reflector;
a second structure that includes a second reflector and is stacked on the first structure; and
an active layer disposed between the first and second structures, in which
a current injection layer is provided in a range in which a light intensity is 1/10 times or more and ⅖ times or less a peak intensity at least inside the first reflector and/or the second reflector.
(2) The surface emitting laser according to (1), in which the current injection layer is disposed in a range in which a light intensity is 1/e² times or more and 1/e times or less the peak intensity.
(3) The surface emitting laser according to (1) or (2), in which the first reflector and/or the second reflector includes first and second constituent layers in this order from the active layer side, and the current injection layer is disposed between the first and second constituent layers.
(4) The surface emitting laser according to (3), in which the first constituent layer is a multilayer film reflector with the number of pairs being one pair or more and six pairs or less.
(5) The surface emitting laser according to (3) or (4), in which the current injection layer is thicker than the first constituent layer and thinner than the second constituent layer.
(6) The surface emitting laser according to any one of (1) to (5), in which the current injection layer includes a compound semiconductor layer having an impurity concentration of 1×10¹⁷ cm⁻³ or more and 1×10¹⁹ cm⁻³ or less.
(7) The surface emitting laser according to any one of (1) to (6), in which the current injection layer includes a compound semiconductor layer containing In.
(8) The surface emitting laser according to any one of (3) to (7), in which the first reflector includes the first and second constituent layers, a mesa including the first constituent layer, the active layer, and the second reflector is formed on the current injection layer, and an electrode is provided on a region of the current injection layer around the mesa.
(9) The surface emitting laser according to (8), in which another current injection layer is provided between the active layer and the second reflector.
(10) The surface emitting laser according to (9), in which the second structure includes a cladding layer disposed between the active layer and the second reflector, and said another current injection layer is disposed between the cladding layer and the second reflector.
(11) The surface emitting laser according to (9), in which the second structure includes a cladding layer disposed between the active layer and the second reflector, and said another current injection layer is provided at least inside the cladding layer.
(12) The surface emitting laser according to any one of (9) to (11), in which another current injection layer is provided between the active layer and the second reflector, another mesa including the second reflector is formed on said another current injection layer, and another electrode is provided on a region of said another current injection layer around said another mesa.
(13) The surface emitting laser according to any one of (3) to (7), in which the second reflector includes the first and second constituent layers, a mesa including the second constituent layer is formed on the current injection layer, and an electrode is provided on a region of the current injection layer around the mesa.
(14) The surface emitting laser according to (13), in which another current injection layer is provided between the first reflector and the active layer.
(15) The surface emitting laser according to (14), in which the first structure includes a cladding layer disposed between the first reflector and the active layer, and said another current injection layer is disposed between the first reflector and the cladding layer.
(16) The surface emitting laser according to (14), in which the first structure includes a cladding layer disposed between the first reflector and the active layer, and
said another current injection layer is provided at least inside the cladding layer.
(17) The surface emitting laser according to any one of (13) to (16), in which another current injection layer is provided between the first reflector and the active layer, another mesa including the active layer, the first constituent layer, and the current injection layer is formed on said another current injection layer, and
another electrode is provided on a region of said another current injection layer around said another mesa.
(18) The surface emitting laser according to (1), in which the current injection layer is provided at least inside the first and second reflectors.
(19) The surface emitting laser according to (18), in which the first reflector includes first and second constituent layers in this order from the active layer side, the second reflector includes first and second constituent layers in this order from the active layer side, a first current injection layer as the current injection layer is provided between the first and second constituent layers of the first reflector, and a second current injection layer as the current injection layer is provided between the first and second constituent layers of the second reflector.
(20) The surface emitting laser according to (19), in which a first mesa including a first constituent layer of the first reflector, the active layer, the first constituent layer of the second reflector, and the second current injection layer is formed on the first current injection layer, a second mesa including the second constituent layer of the second reflector is formed on the second current injection layer, a first electrode is provided on a region of the first current injection layer around the first mesa, and a second electrode is provided on a region of the second current injection layer around the second mesa.
(21) The surface emitting laser according to any one of (1) to (20), in which at least one of the first and second reflectors includes multiple constituent layers that are laminated together and include different types of materials.
(22) The surface emitting laser according to any one of (1) to (20), in which at least one of the first and second reflector includes first and second constituent layers including a material of a same type in this order from the active layer side.
(23) The surface emitting laser according to any one of (1) to (20), in which at least one of the first and second reflectors includes first and second constituent layers including different types of materials in this order from the active layer side.
(24) The surface emitting laser according to any one of (1) to (20), in which at least one of the first and second reflectors includes first and second constituent layers in this order from the active layer side,
the first constituent layer is a semiconductor multilayer film reflector including an impurity semiconductor, and the second constituent layer is a semiconductor multilayer film reflector including an intrinsic semiconductor.
(25) The surface emitting laser according to (1) to (20), in which at least one of the first and second reflectors includes first and second constituent layers in this order from the active layer side, and
the first and second constituent layers are semiconductor multilayer film reflectors having a same conductivity type.
(26) The surface emitting laser according to any one of (21) to (25), in which the current injection layer is disposed between the first and second constituent layers.
(27) The surface emitting laser according to any one of (1) to (26), in which an optical thickness of the current injection layer is 0.5 λ to 1.5 λ.

### REFERENCE SIGNS LIST

10-1 to 10-9, 20, 20-1, 20-2, 30, 30-1, 40, 40-1, 50, 50-1
101 Substrate
102 First reflector
102-1 First constituent layer of first reflector
102-2 Second constituent layer of first reflector
103, 103A, 103B Current injection layer
105 First cladding layer
106 Active layer
107 Second cladding layer
108 Second reflector
108-1 First constituent layer of second reflector
108-2 Second constituent layer of second reflector
109 First electrode (electrode)
110 Second electrode (electrode)
ST1 First structure
ST2 Second structure
M Mesa
M1 First mesa
M2 Second mesa

1. A surface emitting laser comprising:
a first structure including a first reflector;
a second structure that includes a second reflector and is stacked on the first structure; and
an active layer disposed between the first and second structures, wherein
a current injection layer is provided in a range in which a light intensity is 1/10 times or more and ⅖ times or less a peak intensity at least inside the first reflector and/or the second reflector.

2. The surface emitting laser according to claim 1, wherein the current injection layer is disposed in a range in which a light intensity is 1/e² times or more and 1/e times or less the peak intensity.

3. The surface emitting laser according to claim 1, wherein
the first reflector and/or the second reflector includes first and second constituent layers in this order from the active layer side, and
the current injection layer is disposed between the first and second constituent layers.

4. The surface emitting laser according to claim 3, wherein the current injection layer is thicker than the first constituent layer and thinner than the second constituent layer.

5. The surface emitting laser according to claim 1, wherein the current injection layer includes a compound semiconductor layer containing In.

6. The surface emitting laser according to claim 3, wherein
the first reflector includes the first and second constituent layers,
a mesa including the first constituent layer, the active layer, and the second reflector is formed on the current injection layer, and
an electrode is provided on a region of the current injection layer around the mesa.

7. The surface emitting laser according to claim 6, wherein another current injection layer is provided between the active layer and the second reflector.

8. The surface emitting laser according to claim 7, wherein
the second structure includes a cladding layer disposed between the active layer and the second reflector, and
the another current injection layer is disposed between the cladding layer and the second reflector.

9. The surface emitting laser according to claim 7, wherein
the second structure includes a cladding layer disposed between the active layer and the second reflector, and
the another current injection layer is provided at least inside the cladding layer.

10. The surface emitting laser according to claim 7, wherein
another mesa including the second reflector is formed on the another current injection layer, and
another electrode is provided on a region of the another current injection layer around the another mesa.

11. The surface emitting laser according to claim 3, wherein
the second reflector includes the first and second constituent layers,
a mesa including the second constituent layer is formed on the current injection layer, and
an electrode is provided on a region of the current injection layer around the mesa.

12. The surface emitting laser according to claim 11, wherein another current injection layer is provided between the first reflector and the active layer.

13. The surface emitting laser according to claim 12, wherein
the first structure includes a cladding layer disposed between the first reflector and the active layer, and
the another current injection layer is disposed between the first reflector and the cladding layer.

14. The surface emitting laser according to claim 12, wherein
the first structure includes a cladding layer disposed between the first reflector and the active layer, and
the another current injection layer is provided at least inside the cladding layer.

15. The surface emitting laser according to claim 12, wherein
another mesa including the active layer, the first constituent layer, and the current injection layer is formed on the another current injection layer, and
another electrode is provided on a region of the another current injection layer around the another mesa.

16. The surface emitting laser according to claim 1, wherein the current injection layer is provided at least inside the first and second reflectors.

17. The surface emitting laser according to claim 16, wherein
the first reflector includes first and second constituent layers in this order from the active layer side,
the second reflector includes first and second constituent layers in this order from the active layer side,
a first current injection layer as the current injection layer is provided between the first and second constituent layers of the first reflector, and
a second current injection layer as the current injection layer is provided between the first and second constituent layers of the second reflector.

18. The surface emitting laser according to claim 17, wherein
a first mesa including the first constituent layer of the first reflector, the active layer, the first constituent layer of the second reflector, and the second current injection layer is formed on the first current injection layer,
a second mesa including the second constituent layer of the second reflector is formed on the second current injection layer,
a first electrode is provided on a region of the first current injection layer around the first mesa, and
a second electrode is provided on a region of the second current injection layer around the second mesa.
